(19) United States
(12) Patent Application Publication
(10) Pub. No.: US 2025/0280581 A1
(43) Pub. Date: Sep. 4, 2025

(54) GATE SPACER STRUCTURES IN SEMICONDUCTOR DEVICES

(71) Applicant: Taiwan Semiconductor Manufacturing Company, Ltd., Hsinchu (TW)

(72) Inventors: Gerben DOORNBOS, Leuven (BE); Oreste Madia, Bruxelles (BE); Viraj Nilesh Madhiwala, Leuven (BE); Georgios Vellianitis, Leuven (BE); Marcus Johannes Henricus VAN DAL, Linden (BE)

(73) Assignee: Taiwan Semiconductor Manufacturing Company, Ltd., Hsinchu (TW)

(21) Appl. No.: 18/737,310

(22) Filed: Jun. 7, 2024

(30) Foreign Application Priority Data
Feb. 29, 2024 (GR) 20240100149

(51) Int. Cl. H01L 29/66; H01L 21/8238; H01L 27/092; H01L 29/06; H01L 29/08; H01L 29/423; H01L 29/775; H01L 29/786

(52) U.S. Cl. CPC H10D 64/021; H10D 30/014; H10D 30/43; H10D 30/6735; H10D 30/6757; H10D 62/121; H10D 62/151; H10D 64/018; H10D 84/0167; H10D 84/017; H10D 84/038; H10D 84/85

(57) ABSTRACT

A semiconductor device and a method of fabricating the semiconductor device are disclosed. The semiconductor device includes first and second nanostructured channel regions disposed on a substrate, first and second source/drain regions disposed adjacent to the first and second nanostructured channel regions, and first and second gate structures surrounding the first and second nanostructured channel regions. Each of the first and second gate structures includes an outer gate portion and an inner gate portion. The semiconductor device further includes a first inner gate spacer disposed along a sidewall of the inner gate portion of the first gate structure and a second inner gate spacer disposed along a sidewall of the inner gate portion of the second gate structure. The first inner gate spacer includes a first doped dielectric layer and the second inner gate spacer includes a second doped dielectric layer different from the first doped dielectric layer.

### CROSS-REFERENCE TO RELATED APPLICATION

This application claims the benefit of GR patent application Ser. No. 20240100149, filed Feb. 29, 2024, titled “Gate Spacer Structures in Semiconductor Devices,” which is incorporated herein by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device with gate spacer structures, in accordance with some embodiments.

FIGS. 2A-8A, 28A-31A, 2B-8B, and 28B-31B illustrate different cross-sectional views of a semiconductor device with gate spacer structures, in accordance with some embodiments.

FIGS. 2E-2J illustrate device characteristics of a semiconductor device with gate spacer structures, in accordance with some embodiments.

FIG. 9A illustrates an isometric view of another semiconductor device with gate spacer structures, in accordance with some embodiments.

FIGS. 9B and 9C illustrate different cross-sectional views of another semiconductor device with gate spacer structures, in accordance with some embodiments.

FIG. 10 is a flow diagram of a method for fabricating a semiconductor device with gate spacer structures, in accordance with some embodiments.

FIGS. 11-16, 17A-20A, and 17B-20B illustrate cross-sectional views of a semiconductor device with gate spacer structures at various stages of its fabrication process, in accordance with some embodiments.

FIG. 21 is a flow diagram of a method for fabricating another semiconductor device with gate spacer structures, in accordance with some embodiments.

FIGS. 22-27 illustrate cross-sectional views of another semiconductor device with gate spacer structures at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

GAA FETs can include base structures (also referred to as “sheet bases” and “fin bases”) disposed on a substrate, stacks of nanostructured channel regions disposed on the base structures, and gate structures surrounding each of the nanostructured channel regions. Each gate structure can include an outer gate portion and inner gate portions. The outer gate portion can be disposed on a topmost nanostructured channel region in the stack of nanostructured channel regions. Inner gate portions can be disposed between adjacent nanostructured channel regions. The GAA FETs can further include outer gate spacers and inner gate spacers. The outer gate spacers can be disposed on sidewalls of the outer gate portion. Inner gate spacers can be disposed on sidewalls of the inner gate portions and between the adjacent nanostructured channel regions. Some of the challenges of fabricating GAA FETs are performing doping processes on the nanostructured channel regions and minimizing variations in the dopant concentrations among the nanostructured channel regions in the stack of nanostructured channel regions. Variations in the dopant concentrations among the nanostructured channel regions can lead to poor FET performance.

To address the abovementioned challenges, the present disclosure provides example GAA FETs with inner gate spacers that can eliminate the complexities of doping nanostructured channel regions and minimize variations in the dopant concentrations among the nanostructured channel regions. In some embodiments, each nanostructured channel region can have a core channel region and extended channel regions on either sides of core channel region 208Ac and the nanostructured channel regions can be undoped. The top and bottom surfaces of the extended channel regions can be in contact with the inner gate spacers.

In some embodiments, each of inner gate spacers can include a doped dielectric layer, such as a doped silicon oxide (SiO₂) layer, a doped silicon nitride (SiN) layer, a doped silicon oxynitride (SiON) layer, a doped silicon oxycarbide (SiOC) layer, a doped silicon oxycarbon nitride (SiOCN) layer, and any other suitable doped dielectric layer. In some embodiments, the doped dielectric layer can include dopants, such as aluminum (Al), antimony (Sb), phosphorus (P), chlorine (Cl), fluorine (F), bromine (Br), boron (B), zinc (Zn), magnesium (Mg), germanium (Ge), bismuth (Bi), indium (In), gallium (Ga), and a combination thereof. The dopants in the inner gate spacers can provide a doping effect in the extended channel regions by inducing charge carriers (e.g., electrons or holes) in the extended channel regions. The induced charge carriers can reduce the electrical resistance in the nanostructured channel regions, and improve the drive current through the nanostructured channel regions. Thus, with the presence of dopants in the inner gate spacers, the nanostructured channel regions can have the effect of being doped without the presence of dopants in the nanostructured channel regions. As a result, the need for doping the nanostructured channel regions by ion implantation, by in-situ doped epitaxy, by dopant diffusion, or by any other doping methods can be eliminated and the complexities of manufacturing semiconductor device 100 can be reduced.

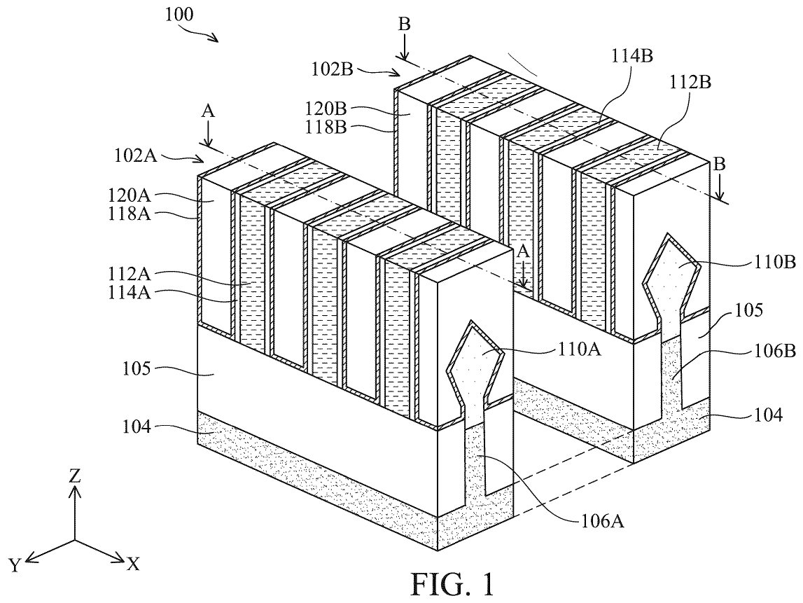

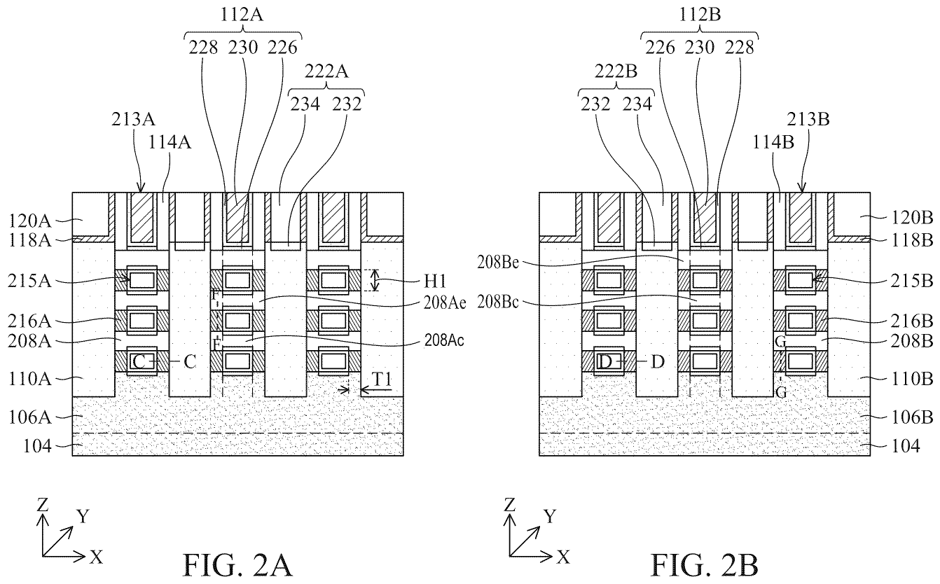

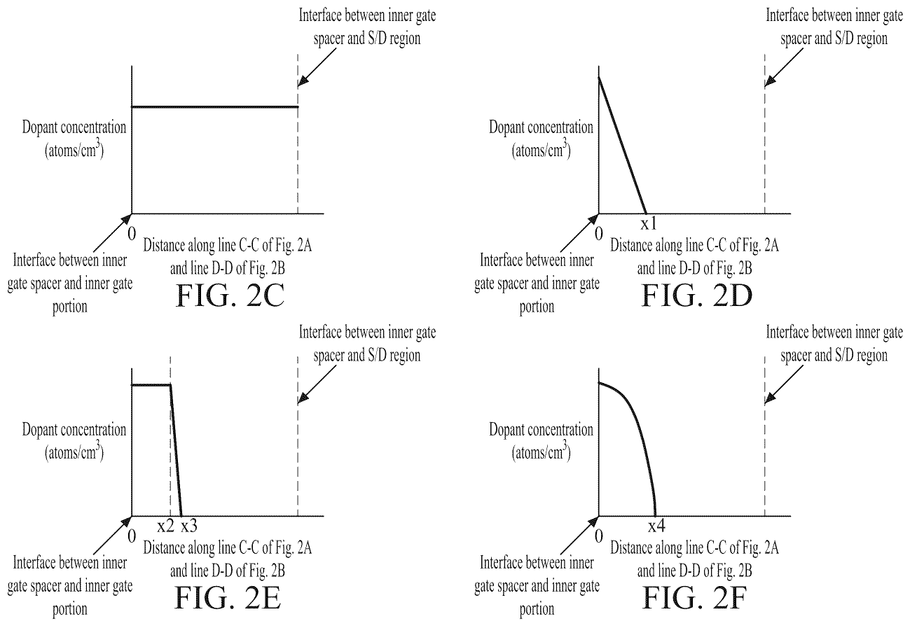

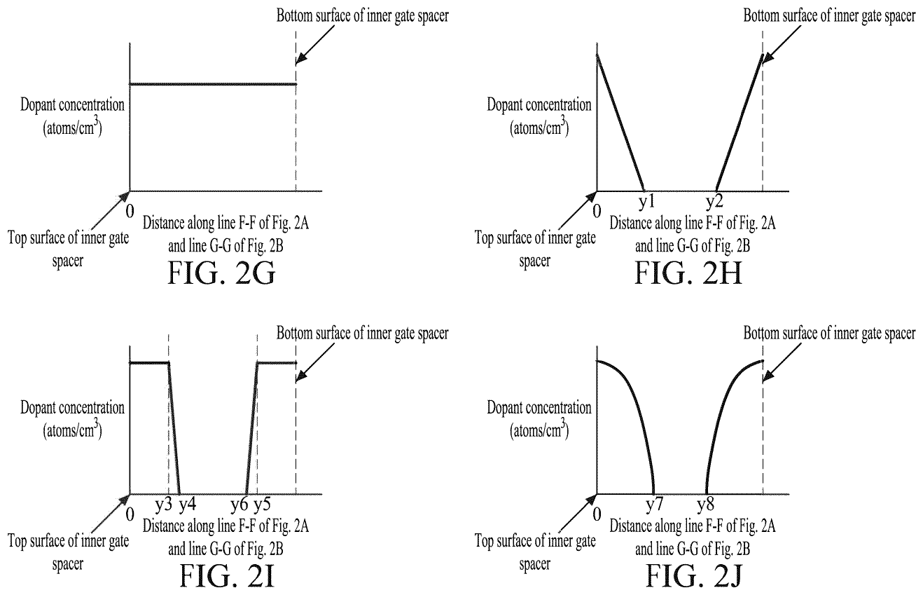

FIG. 1 illustrates an isometric view of a semiconductor device 100 with FETs 102A and 102B, according to some embodiments. In some embodiments, FETs 102A and 102B can represent GAA FETs. In some embodiments, FETs 102A and 102B can be both p-type FETs or n-type FETs or can be one of each conductivity type FETs. FIGS. 2A-8A and 28A-31A illustrate different cross-sectional views of FET 102A, along line A-A of FIG. 1, according to some embodiments. FIGS. 2B-8B and 28B-31B illustrate different cross-sectional views of FET 102B, along line B-B of FIG. 1, according to some embodiments. FIGS. 2A-8A, 28A-31A, 2B-8B, and 28B-31B illustrate cross-sectional views with additional structures that are not shown in FIG. 1 for simplicity. The discussion of elements in FIGS. 1, 2A-8B, 28A-31A, 2B-8B and 28B-31B with the same annotations applies to each other, unless mentioned otherwise.

Semiconductor device 100 can be formed on a substrate 104 with FETs 102A and 102B formed on different regions of substrate 104. There may be other FETs and/or structures (e.g., isolation structures) formed between FETs 102A and 102B on substrate 104. In some embodiments, substrate 104 can be a semiconductor material, such as silicon (Si), Ge, silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include shallow trench isolation (STI) regions 105 disposed on substrate 104. In some embodiments, STI regions 105 can include an insulating material, such as SiO₂, SiN, SiON, SiOC, SiOCN, silicon carbon nitride (SiCN), and silicon germanium oxide (SiGeOₓ).

Referring to FIGS. 1 and 2A, in some embodiments, FET 102A can include a fin-shaped base structure 106A (also referred to as a “sheet base 106A” or a “fin base 106A”) disposed on substrate 104, (ii) nanostructured channel regions 208A disposed on base structure 106A, (iii) S/D regions 110A disposed adjacent to nanostructured channel regions 208A, (iv) gate structures 112A surrounding nanostructured channel regions 208A, (v) outer gate spacers 114A, (vi) inner gate spacers 216A, (vii) etch stop layers (ESLs) 118A disposed directly on S/D regions 110A, (viii) interlayer dielectric (ILD) layers 120A disposed directly on ESLs 118A, and (ix) contact structures 122A disposed on S/D regions 110A.

Similarly, referring to FIGS. 1 and 2B, in some embodiments, FET 102B can include a fin-shaped base structure 106B (also referred to as a “sheet base 106B” or “fin base 106B”) disposed on substrate 104, (ii) nanostructured channel regions 208B disposed on base structure 106B, (iii) S/D regions 110B disposed adjacent to nanostructured channel regions 208B, (iv) gate structures 112B surrounding nanostructured channel regions 208B, (v) outer gate spacers 114B, (vi) inner gate spacers 216B, (vii) ESLs 118B disposed directly on S/D regions 110B, (viii) ILD layers 120B disposed directly on ESLs 118B, and (ix) contact structures 122B disposed on S/D regions 110B. In some embodiments, base structures 106A and 106B can include a material similar to substrate 104. Base structures 106A and 106B can have elongated sides extending along an X-axis.

Referring to FIGS. 2A and 2B, in some embodiments, nanostructured channel regions 208A and 208B can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. Nanostructured channel regions 208A and 208B can include semiconductor materials similar to or different from substrate 104. In some embodiments, nanostructured channel regions 208A and 208B can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials.

In some embodiments, nanostructured channel regions 208A and 208B can be undoped. In some embodiments, nanostructured channel regions 208A and 208B can be unintentionally doped with dopants diffused from outer gate spacers 114A and 114B and/or inner gate spacers 216A and 216B, as described in detail below. The concentration of these unintentional dopants in nanostructured channel regions 208A and 208B can be less than about 5 atomic %. In some embodiments, each of nanostructured channel regions 208A and 208B can have a thickness of about 3 nm to about 15 nm along a Z-axis. Though three nanostructured channel regions 208A are shown under each gate structure 112A and three nanostructured channel regions 208B are shown under each gate structure 112B, FETs 102A and 102B can have any number of nanostructured channel regions 208A and 208B. Though rectangular cross-sections of nanostructured channel regions 208A and 208B are shown, nanostructured channel regions 208A and 208B can have cross-sections of other geometric shapes (e.g., circular, elliptical, triangular, or polygonal).

In some embodiments, each nanostructured channel region 208A can have a core channel region 208Ac and extended channel regions 208Ae on either sides of core channel region 208Ac. Similarly, in some embodiments, each nanostructured channel region 208B can have a core channel region 208Bc and extended channel regions 208Be on either sides of core channel region 208Bc. In some embodiments, core channel regions 208Ac and 208Bc (i) can be disposed under and in physical contact with gate structures 112A and 112B, respectively, (ii) can overlap with gate structures 112A and 112B, respectively, along a vertical direction (e.g., a Z-axis) perpendicular to top surfaces of nanostructured channel regions 208A and 208B, and (iii) can be non-overlapping with outer gate spacers 114A and 114B, and inner gate spacers 216A and 216B along a Z-axis.

In some embodiments, extended channel regions 208Ae and 208Be (i) can be disposed under and in physical contact with outer gate spacers 114A and 114B, respectively, (ii) can be disposed on and in physical contact with inner gate spacers 216A and 216B, respectively, (iii) can be interposed between adjacent inner gate spacers 216A and between adjacent inner gate spacers 216B, respectively, (iv) can overlap with inner gate spacers 216A and 216B, respectively, along a Z-axis, and (v) can be non-overlapping with gate structures 112A and 112B, respectively, along a Z-axis.

Referring to FIGS. 1, 2A, and 2B, in some embodiments, S/D regions 110A and 110B can include an epitaxially-grown semiconductor material, such as Si, and n-type dopants, such as phosphorus and other suitable n-type dopants for n-type FETs 102A and/or 102B. S/D regions 110A and 110B can include an epitaxially-grown semiconductor material, such as Si and SiGe, and p-type dopants, such as boron and other suitable p-type dopants for p-type FETs 102A and/or 102B. Each of S/D regions 110A and 110B may refer to a source or a drain, individually or collectively dependent upon the context.

Referring to FIGS. 2A and 2B, in some embodiments, each gate structure 112A can have an outer gate portion 213A and inner gate portions 215A. Similarly, in some embodiments, each gate structure 112B can have an outer gate portion 213B and inner gate portions 215B. In some embodiments, outer gate portions 213A and 213B can be disposed on and in physical contact with topmost nanostructured channel regions 208A and 208B, respectively. In some embodiments, inner gate portion 215A can be disposed between adjacent nanostructured channel regions 208A and between adjacent inner gate spacers 216A. Similarly, in some embodiments, inner gate portion 215B can be disposed between adjacent nanostructured channel regions 208B and between adjacent inner gate spacers 216B.

Each of gate structures 112A and 112B can be multi-layered structures and can include (i) an interfacial oxide (IL) layer 226, (ii) a high-k (HK) gate dielectric layer 228, and (iii) a conductive layer 230. In some embodiments, IL layer 226 can be disposed directly on topmost nanostructured channel regions 208A and 208B. In some embodiments, IL layer 112A can include SiO₂, SiGeOₓ, or germanium oxide (GeOₓ) and can have a thickness of about 1 nm to about 20 nm. In some embodiments, HK gate dielectric layer 228 can be disposed directly on IL layer 226 and can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of IL layer 226 and HK gate oxide layer 228 can be in contact with sidewalls of outer gate spacers 114A and 114B.

In some embodiments, conductive layer 230 can be disposed on HK gate dielectric layer 228 and can be multi-layered structures. The different layers of conductive layer 230 are not shown for simplicity. In some embodiments, conductive layer 230 can include a work function metal (WFM) layer disposed on HK gate dielectric layer 230 and a gate metal fill layer disposed on the WFM layer. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu). In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials. In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Referring to FIGS. 2A and 2B, outer gate spacers 114A and 114B can electrically isolate outer gate portions 213A and 213B from adjacent S/D regions 110A and 110B and from adjacent contact structures 222A and 222B. In some embodiments, outer gate spacers 114A and 114B can be disposed directly on topmost nanostructured channel regions 208A and 208B, respectively. In some embodiments, outer gate spacers 114A and 114B can include an undoped dielectric layer, such as an undoped SiO₂ layer, an undoped SiN layer, an undoped SiON layer, an undoped SiOC layer, an undoped SiCN layer, an undoped SiOCN layer, and any other suitable undoped dielectric layer.

Inner gate spacers 216A and 216B can electrically isolate inner gate portions 215A and 215B from adjacent S/D regions 110A and 110B. In some embodiments, each of inner gate spacers 216A and 216B can have a height H1 of about 3 nm to about 20 nm and a thickness T1 of about 1 nm to about 10 nm. Within these ranges of height H1 and thickness T1, inner gate spacers 216A and 216B can provide adequately electrically isolate inner gate portions 215A and 215B from adjacent S/D regions 110A and 110B without compromising the device size and manufacturing cost.

In some embodiments, each of inner gate spacers 216A and 216B can include a doped dielectric layer, such as a doped SiO₂ layer, a doped SiN layer, a doped SiON layer, a doped SiOC layer, a doped SiOCN layer, and any other suitable doped dielectric layer. In some embodiments, the doped dielectric layer can include dopants, such as Al, Sb, P, Cl, F, Br, B, Zn, Mg, Ge, Bi, In, Ga, and a combination thereof. The dopants in inner gate spacers 216A and 216B can provide a doping effect in extended channel regions 208Ae and 208Be, respectively, by inducing charge carriers (e.g., electrons or holes) in extended channel regions 208Ae and 208Bc. The induced charge carriers can reduce the electrical resistance in nanostructured channel regions 208A and 208B and improve the drive current through nanostructured channel regions 208A and 208B. Thus, with the presence of dopants in inner gate spacers 216A and 216B, nanostructured channel regions 208A and 208B can have the effect of being doped without the presence of dopants in nanostructured channel regions 208A and 208B. As a result, the need for doping nanostructured channel regions 208A and 208B by ion implantation, by in-situ doped epitaxy, by dopant diffusion, or by any other doping methods can be eliminated and the complexities of manufacturing semiconductor device 100 can be reduced.

In some embodiments, the doped dielectric layer of inner gate spacers 216A and 216B can have a dopant concentration of about 5×10¹⁸ to about 5×10²⁰ atoms/cm³. Below the dopant concentration of about 5×10¹⁸ atoms/cm³, adequate concentration of charge carriers may not be induced in extended channel regions 208Ac and 208Be for adequate reduction in the electrical resistance in nanostructured channel regions 208A and 208B, and adequate improvement of the drive current through nanostructured channel regions 208A and 208B. On the other hand, above the dopant concentration of about 5×10²⁰ atoms/cm³, short channel effects may be induced in FETs 102A and 102B.

FIGS. 2C-2F illustrates different dopant concentration profiles along line C-C of FIG. 2A and line D-D of FIG. 2B, according to some embodiments. The dopant concentration profiles along line D-D of FIG. 2B is similar to the dopant concentration profiles along line C-C of FIG. 2A. In some embodiments, the concentration of dopants across each of inner gate spacers 216A and 216B along line C-C of FIG. 2A and line D-D of FIG. 2B can be substantially constant, as shown in FIG. 2C. In some embodiments, the concentration of dopants near an interface between inner gate spacer 216A and inner gate portion 215A can be higher than the concentration of dopants near an interface between inner gate spacer 216A and S/D region 110A. Similarly, in some embodiments, the concentration of dopants near an interface between inner gate spacer 216B and inner gate portion 215B can be higher than the concentration of dopants near an interface between inner gate spacer 216B and S/D region 110B. In some embodiments, the concentration profile of dopants in inner gate spacer 216A along line C-C of FIG. 2A can have a decreasing slope from the interface between inner gate spacer 216A and inner gate portion 215A to the interface between inner gate spacer 216A and S/D region 110A. Similarly, in some embodiments, the concentration profile of dopants in inner gate spacer 216B along line D-D of FIG. 2B can have a decreasing slope from the interface between inner gate spacer 216B and inner gate portion 215B to the interface between inner gate spacer 216B and S/D region 110B.

In some embodiments, the dopant concentration profiles along line C-C of FIG. 2A can have (i) a decreasing slope from the interface between inner gate spacer 216A and inner gate portion 215A to a location x1 in inner gate spacer 216A, as shown in FIG. 2D, (ii) a substantially constant profile from the interface between inner gate spacer 216A and inner gate portion 215A to a location x2 in inner gate spacer 216A and a decreasing slope from location x2 to a location x3 in inner gate spacer 216A, as shown in FIG. 2E, and (iii) a graded profile that decreases from the interface between inner gate spacer 216A and inner gate portion 215A to a location x4 in inner gate spacer 216A, as shown in FIG. 2F.

FIGS. 2G-2J illustrates different dopant concentration profiles along line F-F of FIG. 2A and line G-G of FIG. 2B, according to some embodiments. The dopant concentration profiles along line G-G of FIG. 2B is similar to the dopant concentration profiles along line F-F of FIG. 2A. In some embodiments, the concentration of dopants across each of inner gate spacers 216A and 216B along line F-F of FIG. 2A and line G-G of FIG. 2B can be substantially constant, as shown in FIG. 2G. In some embodiments, the dopant concentration profiles along line F-F of FIG. 2A can have (i) a decreasing slope from a top surface of inner gate spacer 216A to a location y1 in inner gate spacer 216A, as shown in FIG. 2H, (ii) a decreasing slope from a bottom surface of inner gate spacer 216A to a location y2 in inner gate spacer 216A, as shown in FIG. 2H, (iii) a substantially constant profile from the top surface of inner gate spacer 216A to a location y3 in inner gate spacer 216A and a decreasing slope from location y3 to a location y4 in inner gate spacer 216A, as shown in FIG. 2I, (iv) a substantially constant profile from the bottom surface of inner gate spacer 216A to a location y5 in inner gate spacer 216A and a decreasing slope from location y5 to a location y6 in inner gate spacer 216A, as shown in FIG. 2I, (v) a graded profile that decreases from the top surface of inner gate spacer 216A to a location y7 in inner gate spacer 216A, as shown in FIG. 2J, and (vi) a graded profile that decreases from the bottom surface of inner gate spacer 216A to a location y8 in inner gate spacer 216A, as shown in FIG. 2J.

In some embodiments, the dopants in inner gate spacers 216A can be the same or different from the dopants in inner gate spacers 216B. In some embodiments, the dopants in inner gate spacers 216A and 216B can depend on the conductivity type of FETs 102A and 102B. In some embodiments, inner gate spacers 216A can include n-type dopants, such as P, Cl, F, and Br for n-type FET 102A and inner gate spacers 216B can include p-type dopants, such as Al, B, and Ga for p-type FET 102B. In some embodiments, both FETs 102A and 102B can be n-type or p-type and the dielectric material, the dopants, and/or the dopant concentrations in inner gate spacers 216A and 216B can be different from each other to have FETs 102A and 102B with different threshold voltages. In some embodiments, inner gate spacers 216A can include n-type dopants, such as P, Cl, F, and Br and inner gate spacers 216B can include p-type dopants, such as Al, B, and Ga to vary the threshold voltages of FETs 102A and 102B with respect to each other. The presence of n-type dopants in inner gate spacers 216A can provide a negative shift to the threshold voltage of FET 102A compared to a FET without dopants in inner gate spacers. And, the presence of p-type dopants in inner gate spacers 216B can provide a positive shift to the threshold voltage of FET 102B compared to a FET without dopants in inner gate spacers. Thus, with the use of different dopants in inner gate spacers 216A and 216B, FETs 102A and 102B of same conductivity but of different threshold voltages can be achieved on the same substrate 104.

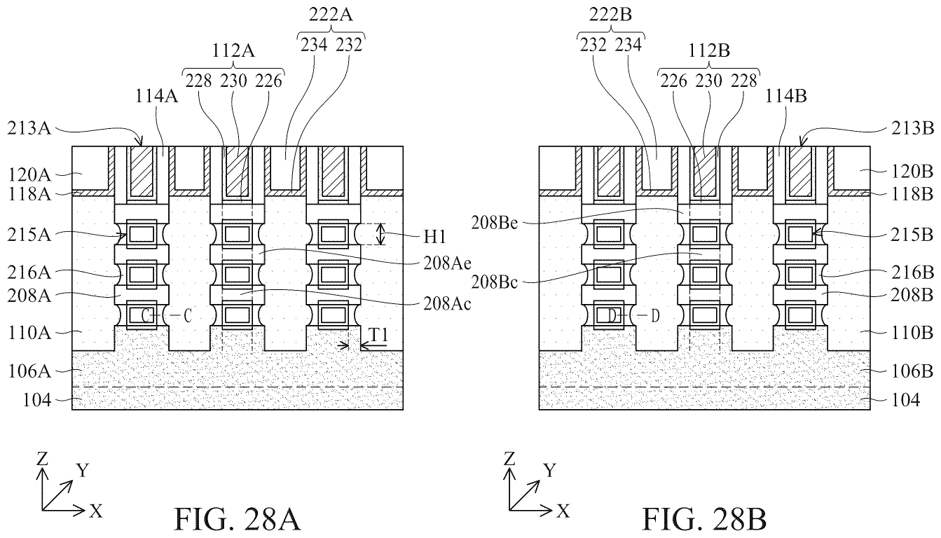

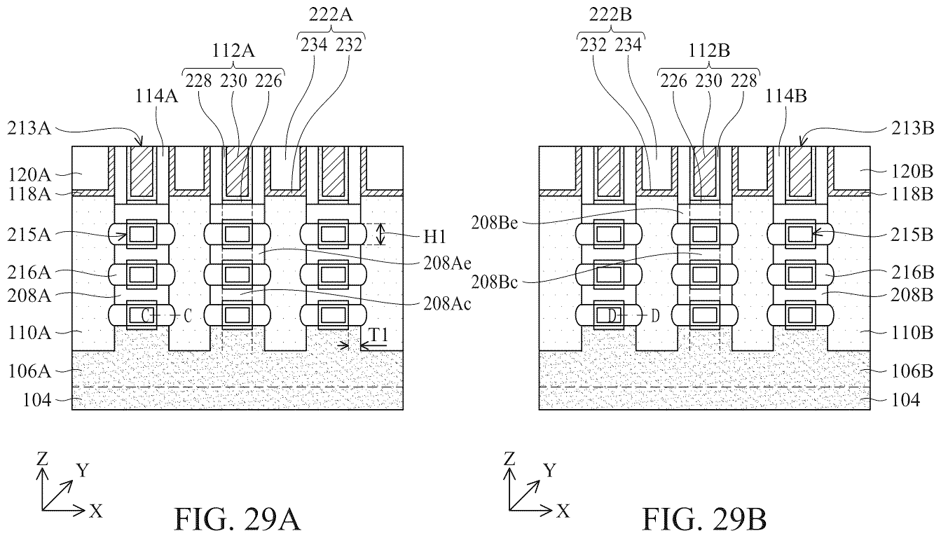

In some embodiments, inner gate spacers 216A and 216B can have sidewalls with linear cross-sectional profiles, as shown in FIGS. 2A and 2B. In some embodiments, inner gate spacers 216A and 216B can have sidewalls facing S/D regions 110A and 110B, respectively, which can have (i) concave-shaped cross-sectional profiles, as shown in FIGS. 28A and 28B, or (ii) convex-shaped cross-sectional profiles, as shown in FIGS. 29A and 29B. In some embodiments, sidewalls of inner gate spacers 216A and 216B can protrude into S/D regions 110A and 110B, respectively, as shown in FIGS. 29A and 29B.

Referring to FIGS. 2A and 2B, in some embodiments, ESLs 118A and 118B can be disposed directly on S/D regions 110A and 110B. In some embodiments, ESLs 118A and 118B can have a dielectric constant of about 4 to about 7 and can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 120A and 120B can be disposed directly on ESLs 118A and 118B. In some embodiments, ILD layers 118 can include an insulating material, such as SiO₂, SiN, SiON, SiCN, and SiOCN.

In some embodiments, each of contact structures 222A and 222B can include (i) a silicide layer 232, and (ii) contact plugs 234 disposed on silicide layer 232. In some embodiments, silicide layer 232 in n-type FETs 102A and 102B can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, silicide layer 232 in p-type FETs 102A and 102B can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, contact plug 234 can include conductive materials, such as Co, W, Ru, Al, Mo, Ir, Ni, Osmium (Os), rhodium (Rh), other suitable conductive materials, and a combination thereof.

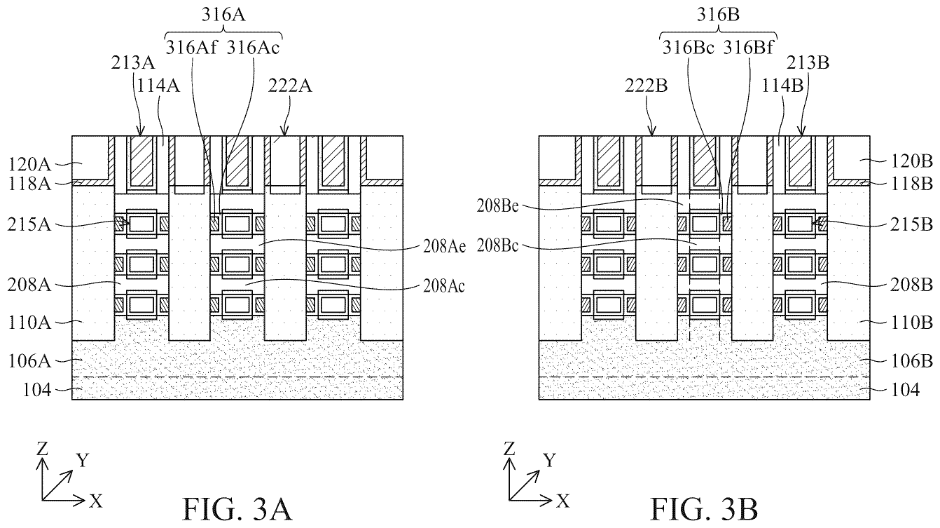

Referring to FIGS. 3A and 3B, in some embodiments, FET 102A can have inner gate spacers 316A instead of inner gate spacers 216A of FIG. 2A and FET 102B can have inner gate spacers 316B instead of inner gate spacers 216B of FIG. 2B. The discussion of inner gate spacers 216A and 216B applies to inner gate spacers 316A and 316B, respectively, unless mentioned otherwise. In some embodiments, inner gate spacer 316A can include a spacer fill layer 316Af and a spacer liner layer 316Ac (also referred to as a “spacer cladding layer 316Ac”). Similarly, inner gate spacer 316B can include a spacer fill layer 316Bf and a spacer liner layer 316Bc (also referred to as a “spacer cladding layer 316Bc”). In some embodiments, Spacer liner layers 316Ac and 316Bc can have C-shaped cross-sectional profiles. Spacer liner layers 316Ac and 316Bc can cover top and bottom surfaces of spacer fill layers 316Af and 316Bf and can cover sidewalls of spacer fill layers 316Af and 316Bf facing inner gate portions 215A and 215B. Top and bottom surfaces of spacer liner layers 316Ac can be in physical contact with extended channel regions 208Ae and sidewalls of spacer liner layers 316Ac can be in physical contact with inner gate portions 215A. Similarly, top and bottom surfaces of spacer liner layers 316Bc can be in physical contact with extended channel regions 208Be and sidewalls of spacer liner layers 316Bc can be in physical contact with inner gate portions 215B.

In some embodiments, each of spacer fill layers 316Af and 316Bf can include an undoped dielectric layer and each of spacer liner layers 316Ac and 316Bc can include a doped dielectric layer. The dielectric layers of spacer fill layers 316Af and 316Bf and spacer liner layers 316Ac and 316Bc can include SiO₂, SiN, SiON, SiOC, SiOCN, or any other suitable dielectric material. In some embodiments, the dielectric materials of spacer fill layers 316Af and 316Bf and spacer liner layers 316Ac and 316Bc can be different from each other. In some embodiments, spacer fill layers 316Af and 316Bf can have undoped oxide layers (e.g., undoped SiO₂ or SiOC) and spacer liner layers 316Ac and 316Bc can have doped nitride layers (e.g., doped SiN, SiON, or SiOCN). In some embodiments, each of spacer fill layers 316Af and 316Bf can include a lightly-doped dielectric layer and each of spacer liner layers 316Ac and 316Bc can include a doped dielectric layer with a dopant concentration greater than a dopant concentration of the lightly-doped dielectric layer. In some embodiments, the lightly-doped dielectric layer and doped dielectric layer can include dopants, such as Al, Sb, P, Cl, F, Br, B, Zn, Mg, Ge, Bi, In, Ga, and a combination thereof. In some embodiments, each of spacer liner layers 316Ac and 316Bc can have a thickness of about 0.3 nm to about 2 nm. Within this range of thickness, spacer liner layers 316Ac and 316Bc may have adequate dopant concentration to induce adequate concentration of charge carriers in extended channel regions 208Ac and 208Be without compromising the device size and manufacturing cost.

In some embodiments, the dopants in spacer fill layers 316Af and 316Bf can be the same or different from each other and the dopants in spacer liner layers 316Ac and 316Bc can be the same or different from each other. In some embodiments, similar to inner gate spacers 216A and 216B, the dopants in spacer liner layers 316Ac and 316Bc and/or in spacer fill layers 316Af and 316Bf can depend on the conductivity type of FETs 102A and 102B. In some embodiments, spacer fill layers 316Af can be undoped and spacer liner layers 316Ac can include n-type dopants, such as P, Cl, F, and Br for n-type FET 102A or both spacer fill layers 316Af and spacer liner layers 316Ac can include the n-type dopants for n-type FET 102A. In some embodiments, spacer fill layers 316Bf can be undoped and spacer liner layers 316Bc can include p-type dopants, such as Al, B, and Ga for p-type FET 102B or both spacer fill layers 316Bf and spacer liner layers 316Bc can include the p-type dopants for p-type FET 102B. In some embodiments, similar to inner gate spacers 216A and 216B, both FETs 102A and 102B can be n-type or p-type and the dielectric material, the dopants, and/or the dopant concentrations in inner gate spacers 316A and 316B can be different from each other to have FETs 102A and 102B with different threshold voltages.

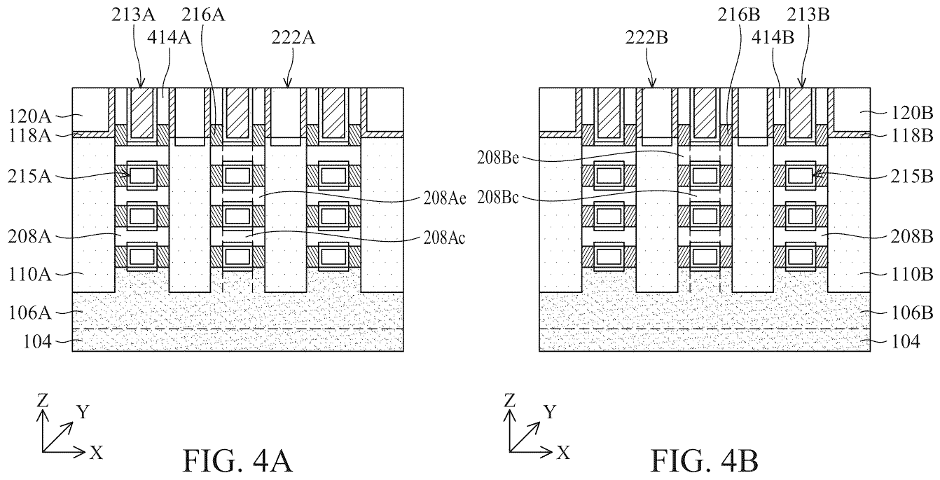

Referring to FIGS. 4A and 4B, in some embodiments, FET 102A can have outer gate spacers 414A instead of outer gate spacers 114A of FIG. 2A and FET 102B can have outer gate spacers 414B instead of outer gate spacers 114B of FIG. 2B. The discussion of outer gate spacers 114A and 114B applies to outer gate spacers 414A and 414B, respectively, unless mentioned otherwise. Unlike outer gate spacers 114A of FIG. 2A, outer gate spacers 414A can be disposed directly on the topmost inner gate spacers 216A, which are disposed directly on the topmost extended channel regions 208Ac. Similarly, unlike outer gate spacers 114B of FIG. 2B, outer gate spacers 414B can be disposed directly on the topmost inner gate spacers 216B, which are disposed directly on the topmost extended channel regions 208Be. In addition, unlike the structures of FIGS. 2A and 2B, sidewalls of the topmost inner gate spacers 216A and 216B can be in physical contact with sidewalls of outer gate portions 213A and 213B, respectively. With the placement of the topmost inner gate spacers 216A and 216B on the topmost extended channel regions 208Ac and 208Be, the dopants in inner gate spacers 216A and 216B can induce charges from both top and bottom surfaces of the topmost extended channel regions 208Ac and 208Bc. As a result, the distribution of induced charges in the topmost extended channel regions 208Ac and 208Be of FIGS. 4A and 4B can be more uniform compared to that in the topmost extended channel regions 208Ac and 208Bc of FIGS. 2A and 2B.

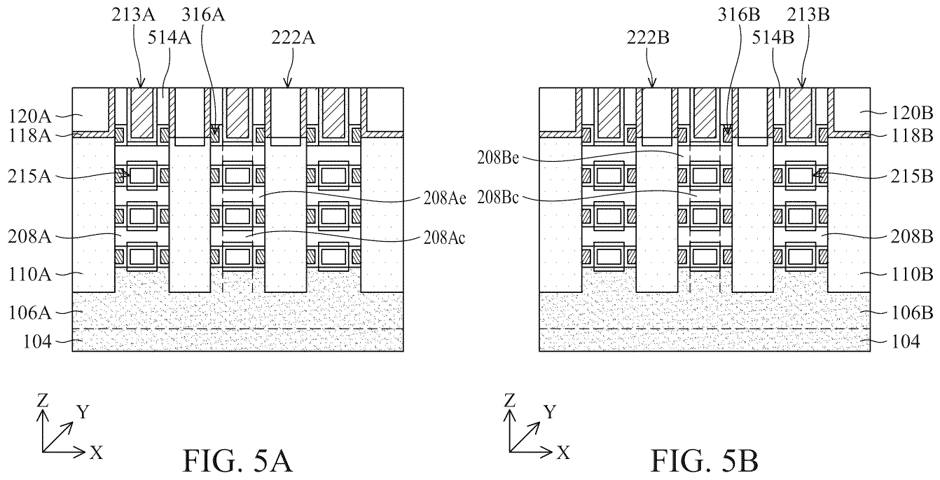

Referring to FIGS. 5A and 5B, in some embodiments, FET 102A can have outer gate spacers 514A instead of outer gate spacers 114A of FIG. 3A and FET 102B can have outer gate spacers 514B instead of outer gate spacers 114B of FIG. 3B. The discussion of outer gate spacers 114A and 114B applies to outer gate spacers 514A and 514B, respectively, unless mentioned otherwise. Unlike outer gate spacers 114A of FIG. 3A, outer gate spacers 514A can be disposed directly on the topmost inner gate spacers 316A, which are disposed directly on the topmost extended channel regions 208Ae. Similarly, unlike outer gate spacers 114B of FIG. 3B, outer gate spacers 514B can be disposed directly on the topmost inner gate spacers 316B, which are disposed directly on the topmost extended channel regions 208Be. In addition, unlike the structures of FIGS. 3A and 3B, sidewalls of the topmost inner gate spacers 316A and 316B can be in physical contact with sidewalls of outer gate portions 213A and 213B, respectively.

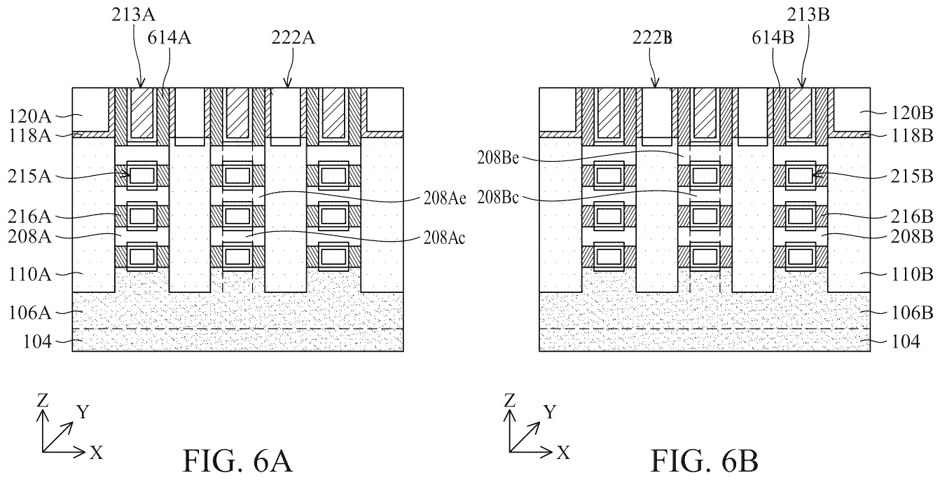

Referring to FIGS. 6A and 6B, in some embodiments, FET 102A can have outer gate spacers 614A instead of outer gate spacers 114A of FIG. 2A and FET 102B can have outer gate spacers 614B instead of outer gate spacers 114B of FIG. 2B. The discussion of outer gate spacers 114A and 114B applies to outer gate spacers 614A and 614B, respectively, unless mentioned otherwise. In some embodiments, outer gate spacers 614A can have doped dielectric layers similar to the doped dielectric layers of inner gate spacers 216A and outer gate spacers 614B can have doped dielectric layers similar to the doped dielectric layers of inner gate spacers 216B.

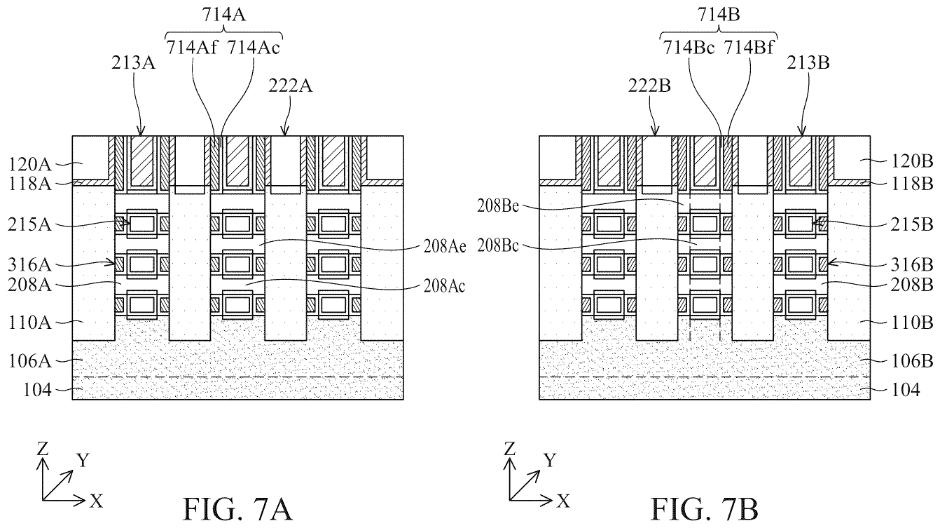

Referring to FIGS. 7A and 7B, in some embodiments, FET 102A can have outer gate spacers 714A instead of outer gate spacers 114A of FIG. 2A and FET 102B can have outer gate spacers 714B instead of outer gate spacers 114B of FIG. 2B. The discussion of outer gate spacers 114A and 114B applies to outer gate spacers 714A and 714B, respectively, unless mentioned otherwise. In some embodiments, outer gate spacer 714A can include a spacer fill layer 714Af and a spacer liner layer 714Ac (also referred to as a “spacer cladding layer 714Ac”). Similarly, outer gate spacers 714B can include a spacer fill layer 714Bf and a spacer liner layer 714Bc (also referred to as a “spacer cladding layer 714Bc”). Spacer liner layers 714Ac and 714Bc can cover bottom surfaces of spacer fill layers 714Af and 714Bf and can cover sidewalls of spacer fill layers 714Af and 714Bf facing outer gate portions 213A and 213B. Bottom surfaces of spacer liner layers 714Ac can be in physical contact with the topmost extended channel regions 208Ac and bottom surfaces of spacer liner layers 714Bc can be in physical contact with extended channel regions 208Be. Sidewalls of spacer liner layers 714Ac can be in physical contact with outer gate portions 213A and sidewalls of spacer liner layers 714Bc can be in physical contact with outer gate portions 213B. Spacer fill layers 714Af and 714Bf can have a doped dielectric layer similar to that of spacer fill layers 316Af and 316Bf, respectively. Spacer liner layers 714Ac and 714Bc can have an undoped dielectric layer or a lightly-doped dielectric layer similar to that of spacer liner layers 316Ac and 316Bc.

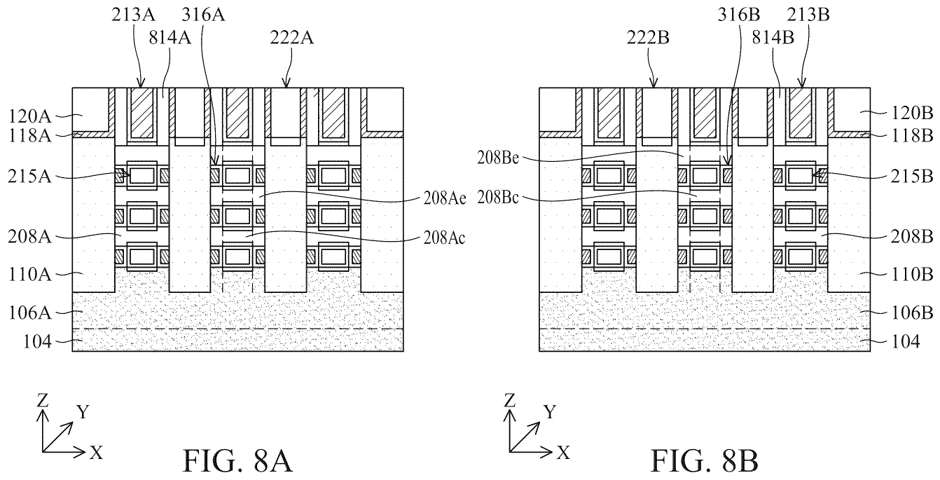

Referring to FIGS. 8A and 8B, in some embodiments, FET 102A can have outer gate spacers 814A instead of outer gate spacers 114A of FIG. 3A and FET 102B can have outer gate spacers 814B instead of outer gate spacers 114B of FIG. 3B. The discussion of outer gate spacers 114A and 114B applies to outer gate spacers 814A and 814B, respectively, unless mentioned otherwise. In some embodiments, outer gate spacers 814A can have doped dielectric layers similar to the doped dielectric layers of spacer liner layers 316Ac and outer gate spacers 814B can have doped dielectric layers similar to the doped dielectric layers of spacer liner layers 316Bc.

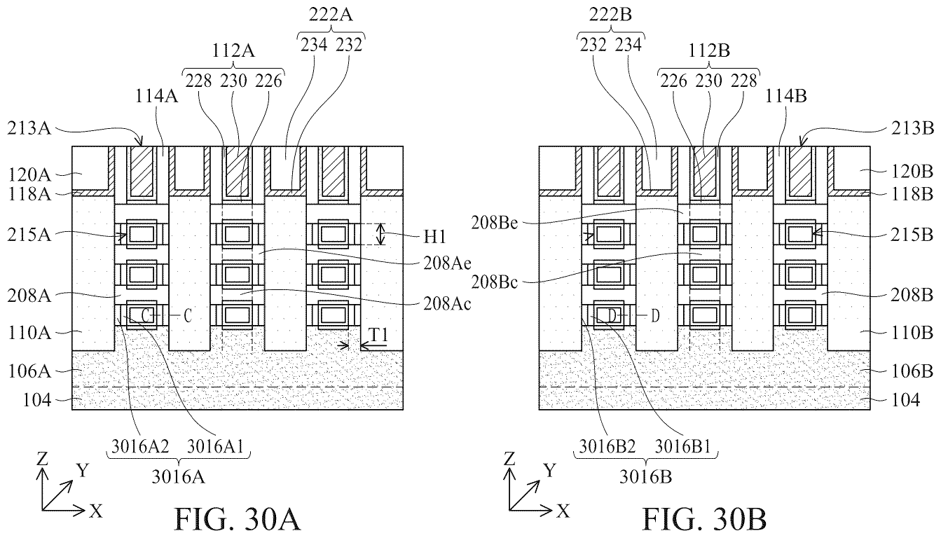

Referring to FIGS. 30A and 30B, in some embodiments, FET 102A can have inner gate spacers 3016A instead of inner gate spacers 216A of FIG. 2A and FET 102B can have inner gate spacers 3016B instead of inner gate spacers 216B of FIG. 2B. The discussion of inner gate spacers 216A and 216B applies to inner gate spacers 3016A and 3016B, respectively, unless mentioned otherwise. In some embodiments, inner gate spacer 3016A can include sub-spacers 3016A1 and 3016A2. Similarly, inner gate spacer 3016B can include sub-spacers 3016B1 and 3016B2. In some embodiments, each of sub-spacers 3016A1, 3016A2, 3016B1, and 3016B2 can include a doped dielectric layer, such as a doped SiO₂ layer, a doped SiN layer, a doped SiON layer, a doped SiOC layer, a doped SiOCN layer, and any other suitable doped dielectric layer. In some embodiments, the doped dielectric layer can include dopants, such as Al, Sb, P, Cl, F, Br, B, Zn, Mg, Ge, Bi, In, Ga, and a combination thereof, and can have a dopant concentration of about 5×10¹⁸ to about 5×10²⁰ atoms/cm³. In some embodiments, sub-spacers 3016A1 and 3016B1 can include a first dopant concentration and sub-spacers 3016A2 and 3016B2 can include a second dopant concentration that is different from the first dopant concentration. In some embodiments, sub-spacers 3016A1 and 3016B1 can be in contact with inner gate portions 215A and 215B, respectively, and sub-spacers 3016A2 and 3016B2 can be in contact with S/D regions 110A and 110B, respectively.

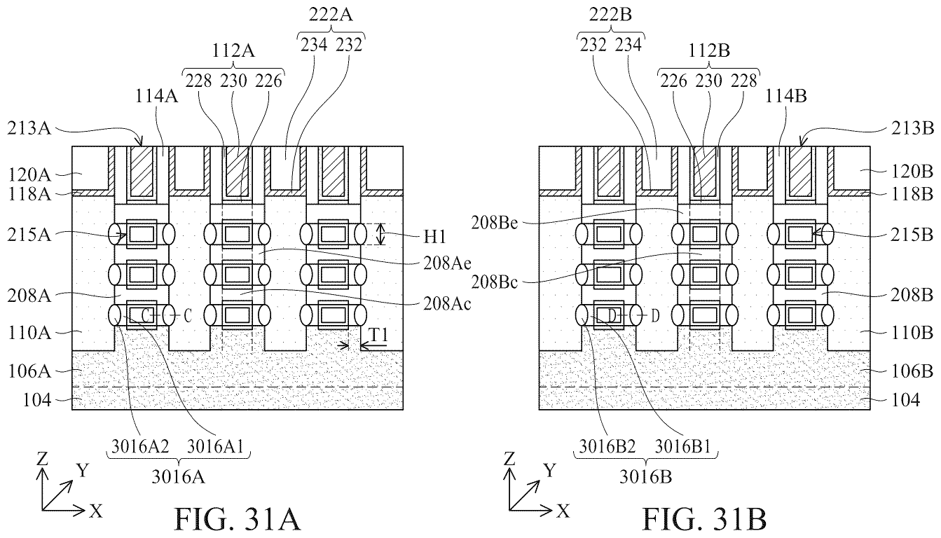

In some embodiments, sub-spacers 3016A1, 3016A2, 3016B1, and 3016B2 can have sidewalls with linear cross-sectional profiles, as shown in FIGS. 30A and 30B. In some embodiments, sub-spacers 3016A1 and 3016B1 can have sidewalls facing S/D regions 110A and 110B, respectively, which can have concave-shaped cross-sectional profiles, as shown in FIGS. 31A and 31B. In some embodiments, sub-spacers 3016A2 and 3016B2 can have sidewalls with convex-shaped cross-sectional profiles, as shown in FIGS. 31A and 31B. In some embodiments, sidewalls of sub-spacers 3016A2 and 3016B2 can protrude into S/D regions 110A and 110B, respectively, as shown in FIGS. 31A and 31B.

In some embodiments, FET 102A can have the structure of FIG. 2A, while FET 102B can have the structure of FIG. 2B, 3B, 4B, 5B, 6B, 7B, 8B, 28B, 29B, 30B, or 31B. In some embodiments, FET 102A can have the structure of FIG. 3A, while FET 102B can have the structure of FIG. 2B, 3B, 4B, 5B, 6B, 7B, 8B, 28B, 29B, 30B, or 31B. In some embodiments, FET 102A can have the structure of FIG. 4A, while FET 102B can have the structure of FIG. 2B, 3B, 4B, 5B, 6B, 7B, 8B, 28B, 29B, 30B, or 31B. In some embodiments, FET 102A can have the structure of FIG. 5A, while FET 102B can have the structure of FIG. 2B, 3B, 4B, 5B, 6B, 7B, 8B, 28B, 29B, 30B, or 31B. In some embodiments, FET 102A can have the structure of FIG. 6A, while FET 102B can have the structure of FIG. 2B, 3B, 4B, 5B, 6B, 7B, 8B, 28B, 29B, 30B, or 31B. In some embodiments, FET 102A can have the structure of FIG. 7A, while FET 102B can have the structure of FIG. 2B, 3B, 4B, 5B, 6B, 7B, 8B, 28B, 29B, 30B, or 31B. In some embodiments, FET 102A can have the structure of FIG. 8A, while FET 102B can have the structure of FIG. 2B, 3B, 4B, 5B, 6B, 7B, 8B, 28B, 29B, 30B, or 31B. In some embodiments, instead of the structures of FIGS. 2A-8A, 28A-31A, 2B-8B, and 28B-31B being different structures of two FETs 102A and 102B, the structures of FIGS. 2A-8A, 28A-31A, 2B-8B, and 28A-31B can be the structures of 22 different FETs disposed on the same substrate 104 of semiconductor device 100.

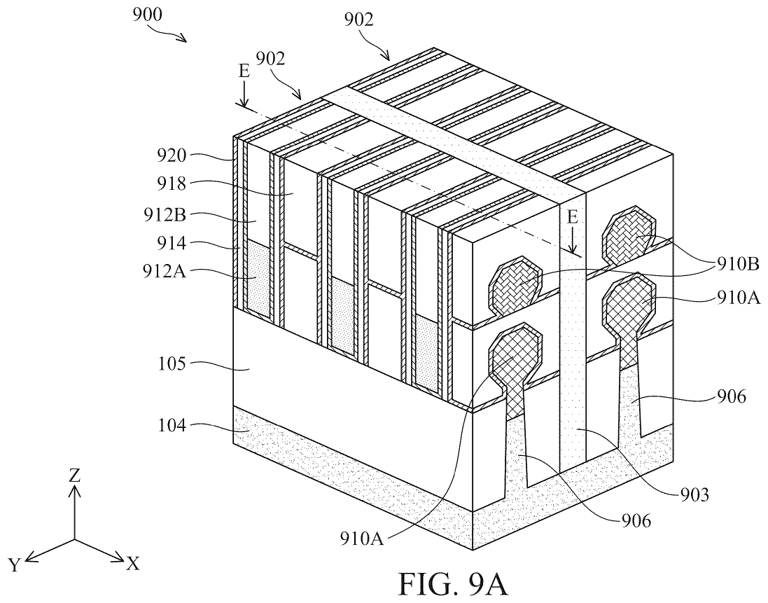

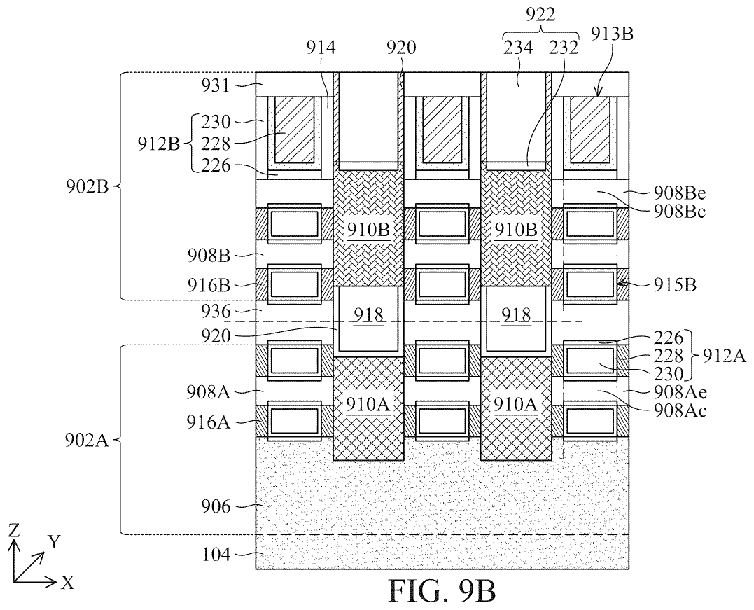

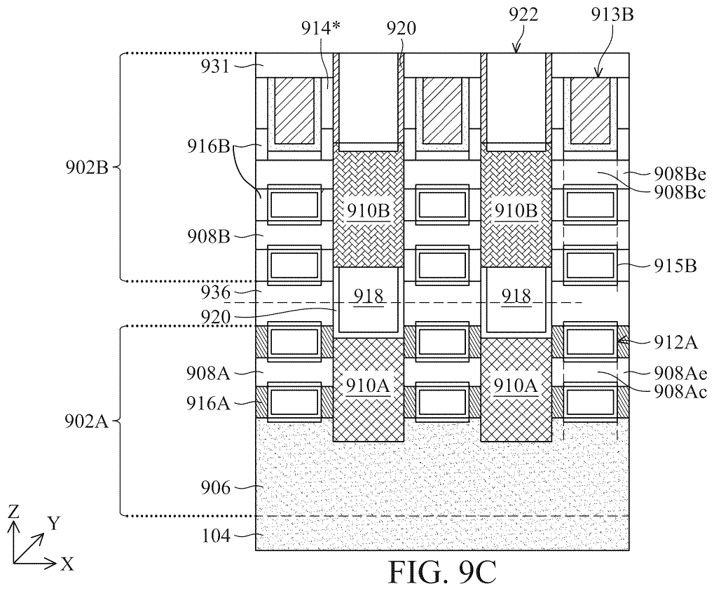

FIG. 9A illustrates an isometric view of a semiconductor device 900, according to some embodiments. FIGS. 9B and 9C illustrate different cross-sectional views of semiconductor device 100 along line E-E of FIG. 9A, according to some embodiments. FIGS. 9B and 9C illustrate views of semiconductor device 100 with additional structures that are not shown in FIG. 9A for simplicity. The discussion of elements in FIGS. 1, 2A-8B, 28A-18A, 2B-8B, 28B-31B, and 9A-9C with the same annotations applies to each other, unless mentioned otherwise.

Referring to FIGS. 9A and 9B, semiconductor device 100 can include (i) substrate 104, (ii) stacked FETs 902 disposed on substrate 104, and (iii) an electrical isolation structure 903 disposed between stacked FETs 902. In some embodiments, each stacked FET 902 can include (i) a base structure 906 disposed on substrate 104, (ii) STI regions 105 disposed on substrate 104 and adjacent to base structure 906, (iii) a GAA FET 902A disposed on base structure 906 and STI regions 105, (iv) a GAA FET 902B disposed on GAA FET 902A, (v) ESLs 918, (vi) ILD layers 920, and (vii) channel isolation layers 936 disposed between GAA FETs 902A and 902B. In some embodiments, fin structures 906 can include a material similar to substrate 104 and extend along an X-axis. The discussion of the materials of ESLs 118A and ILD layers 120A applies to the materials of ESLs 918 and ILD layers 920. Electrical isolation structure 903 can include a dielectric oxide layer or a dielectric nitride layer.

Stacked FET 902 can be referred to as a “complementary FET (CFET) 902” when GAA FET 902A has a conductivity type different from that of GAA FET 902B. In some embodiments, GAA FET 902A can be p-type and GAA FET 902B can be n-type. In some embodiments, GAA FET 902A can include (i) nanostructured channel regions 908A disposed on fin structure 906, (ii) S/D regions 910A disposed adjacent to nanostructured channel regions 908A, (iii) gate structures 912A surrounding nanostructured channel regions 908A, and (iv) inner gate spacers 916A. In some embodiments, GAA FET 902B can include (i) nanostructured channel regions 908B disposed on GAA FET 902A, (ii) S/D regions 910B disposed adjacent to nanostructured channel regions 908V, (iii) gate structures 912B surrounding nanostructured channel regions 908B, (iv) outer gate spacers 914, (v) inner gate spacers 916B, (vi) contact structures 922, and (vii) gate capping layers 931.

The discussion of nanostructured channel regions 208A and 208B applies to nanostructured channel regions 908A and 908B, respectively, unless mentioned otherwise. In some embodiments, each nanostructured channel region 908A can have a core channel region 908Ac and extended channel regions 908Ac. Similarly, in some embodiments, each nanostructured channel region 908B can have a core channel region 908Bc and extended channel regions 908Be. In some embodiments, core channel regions 908Ac and 908Bc (i) can be disposed under and in physical contact with gate structures 912A and 912B, respectively, (ii) can overlap with gate structures 912A and 912B, respectively, along a Z-axis, and (iii) can be non-overlapping with inner gate spacers 916A and 916B along a Z-axis.

In some embodiments, extended channel regions 908Ac and 908Be (i) can be disposed on and in physical contact with inner gate spacers 916A and 916B, respectively, and (ii) can be interposed between adjacent inner gate spacers 916A and between adjacent inner gate spacers 916B, respectively, (iii) can overlap with inner gate spacers 916A and 916B, respectively, along a Z-axis, and (iv) can be non-overlapping with gate structures 912A and 912B, respectively, along a Z-axis.

S/D regions 910A can include an epitaxially-grown semiconductor material, such as Si and SiGe, and p-type dopants, such as boron and other suitable p-type dopants for p-type GAA FET 902A. S/D regions 910B can include an epitaxially-grown semiconductor material, such as Si, and n-type dopants, such as phosphorus and other suitable n-type dopants for n-type GAA FET 902B.

In some embodiments, each gate structure 912B can have an outer gate portion 913B and inner gate portions 915B. Outer gate portions 913B can be disposed on and in physical contact with topmost nanostructured channel regions 908B and inner gate portion 915B can be disposed between adjacent nanostructured channel regions 908B and between adjacent inner gate spacers 916B. Each of gate structures 912A and 912B can be multi-layered structures and can include (i) IL layer 226, (ii) HK gate dielectric layer 228, and (iii) conductive layer 230.

The discussion of outer gate spacers 114A applies to outer gate spacers 914, unless mentioned otherwise. Outer gate spacers 914 can electrically isolate outer gate portions 913B from adjacent S/D regions 910B and from adjacent contact structures 922. In some embodiments, outer gate spacers 914 can be disposed directly on topmost nanostructured channel regions 908B. In some embodiments, GAA FET 902B can have outer gate spacers 614B of FIG. 6B, outer gate spacers 714B of FIG. 7B, or outer gate spacers 814B of FIG. 8B, instead of outer gate spacers 914.

The discussion of inner gate spacers 216A and 216B applies to inner gate spacers 916A and 916B, respectively, unless mentioned otherwise. Inner gate spacers 916A and 916B can electrically isolate gate structures 912A and inner gate portions 915B from adjacent S/D regions 910A and 910B. Similar to inner gate spacers 216A and 216B, inner gate spacers 916A and 916B can include a doped dielectric layer and the dopants in inner gate spacers 916A and 916B can provide a doping effect in extended channel regions 908Ae and 908Be, respectively, by inducing charge carriers (e.g., electrons or holes) in extended channel regions 908Ac and 908Bc. In some embodiments, the concentration profile of dopants in inner gate spacer 916A can have a decreasing slope from the interface between inner gate spacer 916A and gate structure 912A to the interface between inner gate spacer 916A and S/D region 910A. Similarly, in some embodiments, the concentration profile of dopants in inner gate spacer 916B can have a decreasing slope from the interface between inner gate spacer 916B and inner gate portion 915B to the interface between inner gate spacer 916B and S/D region 910B.

In some embodiments, inner gate spacers 916A can include p-type dopants, such as Al, B, and Ga for p-type GAA FET 902A and inner gate spacers 916B can include n-type dopants, such as P, Cl, F, and Br for n-type GAA FET 102B. In some embodiments, both GAA FETs 902A and 902B can be n-type or p-type and the dielectric material, the dopants, and/or the dopant concentrations in inner gate spacers 916A and 916B can be different from each other to have GAA FETs 902A and 902B with different threshold voltages. In some embodiments, GAA FETs 902A can have inner gate spacers 316A of FIG. 3A, or inner gate spacers 3016A of FIG. 30A, instead of inner gate spacers 916A. And, GAA FETs 902B can have inner gate spacers 316B of FIG. 3B, or inner gate spacers 3016B of FIG. 30B, instead of inner gate spacers 916B.

In some embodiments, each of contact structures 922 can include (i) silicide layer 232, and (ii) contact plugs 234 disposed on silicide layer 232. Gate capping layers 931 can protect the underlying outer gate portions 913B from structural and/or compositional degradation during subsequent processing of semiconductor device 100. In some embodiments, gate capping layers 931 can include a dielectric oxide layer or a dielectric nitride layer. Channel isolation layers 936 can electrically isolate channel regions of GAA FET 902A from the overlying channel regions of GAA FET 902B. In some embodiments, channel isolation layers 936 can include a dielectric material with a dielectric constant ranging from about 3 to about 25. In some embodiments, the dielectric material can include SiO₂, SiN, SiON, SiOCN, HfO₂, ZrO₂, or a combination thereof.

Referring to FIG. 9C, in some embodiments, GAA FET 902B can have outer gate spacers 914* instead of outer gate spacers 914 of FIG. 9B. The discussion of outer gate spacers 914 applies to outer gate spacers 914*, unless mentioned otherwise. Unlike outer gate spacers 914 of FIG. 9B, outer gate spacers 914* can be disposed directly on the topmost inner gate spacers 916B, which are disposed directly on the topmost extended channel regions 908Ac. In addition, unlike the structure of FIG. 9B, sidewalls of the topmost inner gate spacers 916B can be in physical contact with sidewalls of outer gate portions 913B. In some embodiments, GAA FET 902A can have inner gate spacers 316A of FIG. 3A, or inner gate spacers 3016A of FIG. 30A, instead of outer gate spacers 916A. In some embodiments, GAA FETs 902A can have inner gate spacers 316A of FIG. 5A, instead of inner gate spacers 916A. And, GAA FETs 902B can have inner gate spacers 316B of FIG. 5B, or inner gate spacers 3016B of FIG. 30B, instead of inner gate spacers 916B.

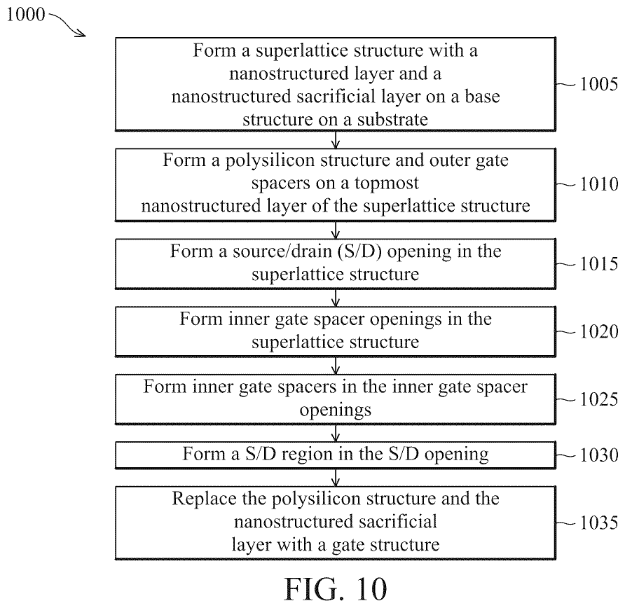

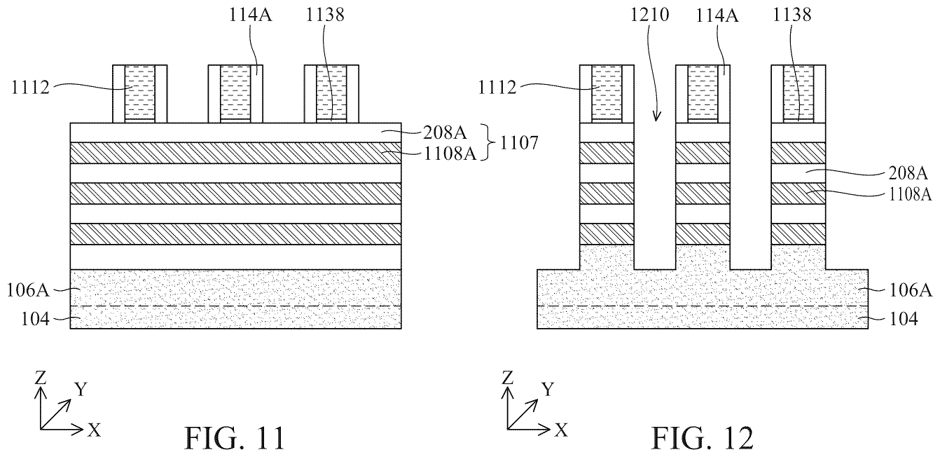

FIG. 10 is a flow diagram of an example method 1000 for fabricating semiconductor device 100 with the cross-sectional view of FIG. 2A, according to some embodiments. For illustrative purposes, the operations illustrated in FIG. 10 will be described with reference to the example fabrication process for fabricating semiconductor device 100 as illustrated in FIGS. 11-16. FIGS. 11-16 are cross-sectional views of semiconductor device 100 along line A-A of FIG. 1 at various stages of fabrication of semiconductor device 100, according to some embodiments. Operations can be performed in a different order or not performed depending on specific applications. It should be noted that method 1000 may not produce a complete semiconductor device 100. Accordingly, it is understood that additional processes can be provided before, during, and after method 1000, and that some other processes may only be briefly described herein. The discussion of elements in FIGS. 1, 2A, 3A, and 11-16 with the same annotations applies to each other, unless mentioned otherwise.

Referring to FIG. 10, in operation 1005, a superlattice structure with a nanostructured layer and a nanostructured sacrificial layer on a base structure on a substrate. For example, as shown in FIG. 11, a superlattice structure 1107 (also referred to as “nanosheet stack 1107”) is formed on base structure 106A, which is formed on substrate 104. Superlattice structure 1107 can include nanostructured layers 208A and nanostructured sacrificial layers 1108A arranged in an alternating configuration. In some embodiments, nanostructured layers 208A can include Si and nanostructured sacrificial layers 1108A can include SiGe.

Referring to FIG. 10, in operation 1010, a polysilicon structure and outer gate spacers are formed on a topmost nanostructured layer of the superlattice structure. For example, as shown in FIG. 11, polysilicon structures 1112 and outer gate spacers 114A are formed on topmost nanostructured layer 208A of superlattice structure 1107. In some embodiments, the formation of polysilicon structures 1112 can include sequential operations of (i) depositing a polysilicon layer (not shown) on superlattice structure 1107, and (ii) performing a patterning process (e.g., lithography process) on the polysilicon layer to form polysilicon structures 1112, as shown in FIG. 11. In some embodiments, SiO₂ layers 1138 can be formed on superlattice structure 1107 prior to the formation of polysilicon structures 1112. During subsequent processing, polysilicon structures 1112, SiO₂ layers 1138, and nanostructured sacrificial layers 1108A can be replaced with gate structures 112A in a gate replacement process.

In some embodiments, the formation of outer gate spacers 114A can include sequential operations of (i) depositing a dielectric material layer (not shown) on polysilicon structures 1112 and on exposed regions of superlattice structure 1107, (ii) performing an anneal process to densify dielectric material layer, and (iii) etching horizontal portions of the densified dielectric material layer on superlattice structure 1107 to form outer gate spacers 114A, as shown in FIG. 11. In some embodiments, outer gate spacers 614A of FIG. 6A, outer gate spacers 714A of FIG. 7A, or outer gate spacers 814A of FIG. 8A can be formed instead of forming outer gate spacers 114A. The process of forming outer gate spacers 614A and 814A can be the same as the process of forming outer gate spacers 114A, except the material of dielectric material layer is different for outer gate spacers 114A, 614A, and 814A. The materials of the dielectric material layer can be the material of outer gate spacers 114A, 614A, and 814A described above with reference to FIGS. 2A, 6A, and 8A. The process of forming outer gate spacers 714A can be the same as the process of forming outer gate spacers 114A, except (i) a doped liner layer can be deposited on polysilicon structures 1112 and on exposed regions of superlattice structure 1107 prior to depositing the dielectric material layer on the doped liner layer, and (ii) etching horizontal portions of the liner layer and the densified dielectric material layer on superlattice structure 1107 to form outer gate spacers 714A. The materials of the doped liner layer and dielectric material layer for forming outer gate spacers 714A can be the materials of spacer liner layer 714Ac and spacer fill layer 714Af described above with reference to FIG. 7A.

Referring to FIG. 10, in operation 1015, a S/D opening is formed in the superlattice structure. For example, as shown in FIG. 12, S/D openings 1210 are formed in superlattice structure 1107. S/D openings 1210 can be formed by etching the portions of superlattice structure 1107 not covered by polysilicon structures 1112. In some embodiments, the etching of superlattice structure 1107 can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar). The etching can be performed at a temperature ranging from about 25° C. to about 200° C. under a pressure from about 5 mTorr to about 50 mTorr. The flow rate of the etching gases can range from about 5 standard cubic centimeters per minute (sccm) to about 100 sccm. The plasma power can range from about 50 W to about 200 W with a bias voltage from about 30 V to about 200 V.

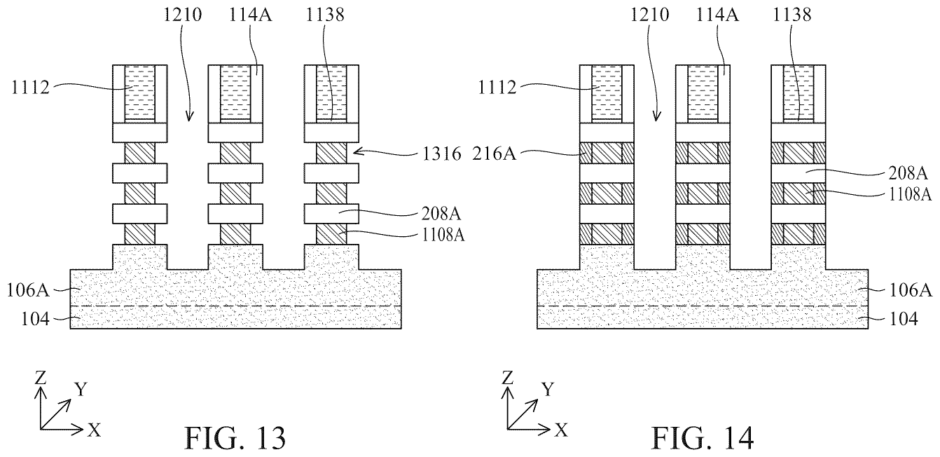

Referring to FIG. 10, in operation 1020, inner gate spacer openings are formed in the superlattice structure. For example, as shown in FIG. 13, inner gate spacer openings 1316 are formed in superlattice structure 1107. The formation of inner gate spacer openings 1316 can include performing an etching process on sidewalls of nanostructured sacrificial layers 1108A facing S/D openings 1210. The etching process can laterally etch nanostructured sacrificial layers 1108A to laterally recess the sidewalls of nanostructured sacrificial layers 1108A with respect to sidewalls of nanostructured layers 208A facing S/D openings 1210. The etching process can include a dry etching process that has a higher etch selectivity for SiGe of nanostructured sacrificial layers 1108A than Si of nanostructured layers 208A. For example, halogen-based chemistries can exhibit etch selectivity that is higher for Ge than for Si. Therefore, halogen gases can etch SiGe faster than Si. In some embodiments, the halogen-based chemistries can include fluorine-based and/or chlorine-based gasses. Alternatively, the etching of nanostructured sacrificial layers 1108A can include a wet etching process with a higher selectivity for SiGe than Si. For example, the wet etching process can include using a mixture of sulfuric acid (H₂SO₄) and hydrogen peroxide (H₂O₂) and/or a mixture of ammonia hydroxide (NH₄OH) with H₂O₂ and deionized (DI) water.

Referring to FIG. 10, in operation 1025, inner gate spacers are formed in the inner gate spacer openings. For example, as shown in FIG. 14, inner gate spacers 216A are formed in inner gate spacer openings 1316. The formation of inner gate spacers 216A can include sequential operations of (i) depositing a doped dielectric material layer (not shown) on the structure of FIG. 13, (ii) performing an anneal process (e.g., a rapid thermal anneal process) on the doped dielectric layer at a temperature of about 500° C. to about 1000° C. in an ambient of argon, nitrogen, oxygen, and/or hydrogen for a time period of about 1 sec to about 30 min, and (iii) etching the doped dielectric material layer to form the structure of FIG. 14. In some embodiments, the etching of the doped dielectric material layer can be an anisotropic dry etching process and can have a higher etching rate along a Z-axis rather than along an X-axis or a Y-axis. As a result, the portions of the doped dielectric material layer in S/D openings 1210 can be etched without etching the portions of the doped dielectric material layer in inner gate spacer openings 1316. The material of the doped dielectric material layer for forming inner gate spacers 216A can be the material of inner gate spacers 216A described above with reference to FIG. 3A.

In some embodiments, depositing the doped dielectric material layer can include depositing a doped SiO₂ layer in an atomic layer deposition (ALD) process, which can include depositing monolayers of dopant-oxygen (D-O) bonds and Si—O bonds in alternating ALD cycles using a dopant precursor, a silicon precursor, and an oxygen precursor (e.g., water (H₂O) or ozone (O₃)) at a temperature of about 150° C. to about 350° C. In some embodiments, the dopant D can include Al, B, Sb, P, Zn, Mg, Ge, Bi, In, or Ga. In some embodiments, depositing the doped dielectric material layer can include depositing a doped SiC layer in an ALD process, which can include depositing monolayers of D-O bonds and Si—O bonds in alternating ALD cycles using a dopant precursor, a silicon precursor, an oxygen precursor, and a carbon precursor (e.g., methane gas (CH₄)) at a temperature of about 150° C. to about 350° C. In some embodiments, depositing the doped dielectric material layer can include depositing a doped SiN or SiON layer in an ALD process, which can include depositing monolayers of D-O bonds and Si—O bonds in alternating ALD cycles using a dopant precursor, a silicon precursor, an oxygen precursor, and a nitrogen precursor (e.g., ammonia gas (NH₃)) at a temperature of about 150° C. to about 350° C. In some embodiments, depositing the doped dielectric material layer can include depositing a doped SiOCN layer in an ALD process, which can include depositing monolayers of D-O bonds and Si—O bonds in alternating ALD cycles using a dopant precursor, a silicon precursor, an oxygen precursor, a carbon precursor, and a nitrogen precursor at a temperature of about 150° C. to about 350° C.

In some embodiments, the silicon precursor can include tetra(ethoxy)silane (Si(OEt)₄), tetraethylorthosilicate, tris(3-tert-pentoxy)silanol, hexachlorodisilane (HCDS). In some embodiments, the dopant precursor for (i) Al dopants can include trimethylaluminium (TMA), tris(ethoxy)aluminum (Al(OEt)₃), aluminumethoxide, or isopropoxydimethylaluminum, (ii) B dopants can include tris-(methoxy)boron (B(OMe)₃) or trimethylborate, (iii) Sb dopants can include ethoxide (Sb(OEt)₃), tris(dimethylamido)antimony (Sb(NMe₂)₃), or tris (trimethylsilyl)antimony ((SiMe₃)₃Sb), (iv) P dopants can include trimethyl phosphate (TMP), (v) Zn dopants can include diethyl zinc (DEZ), (vi) Mg dopants can include bis(cyclopentadienyl)magnesium (Mg(Cp)₂), (vii) Ge dopants can include GeCl₂-dioxane, (viii) Bi dopants can include Bi(N(SiMe₃)₂)₃, (ix) In dopants can include [3-(dimethylamino)propyl]dimethyl indium (DADI), and (x) Ga dopants can include trimethylgallium (TMG).

In some embodiments, inner gate spacers 316A of FIG. 3A can be formed instead of forming inner gate spacers 216A. The process of forming inner gate spacers 316A can include sequential operations of (i) depositing a doped liner layer (not shown) on the structure of FIG. 13, (ii) depositing a doped or undoped dielectric material layer on the liner layer, (iii) performing an anneal process on the doped or undoped dielectric layer, and (iv) etching the doped liner layer and the doped or undoped dielectric material layer to form inner gate spacers 316A. The materials of the doped liner layer and doped or undoped dielectric material layer for forming inner gate spacers 316A can be the materials of spacer liner layer 314Ac and spacer fill layer 314Af described above with reference to FIG. 3A.

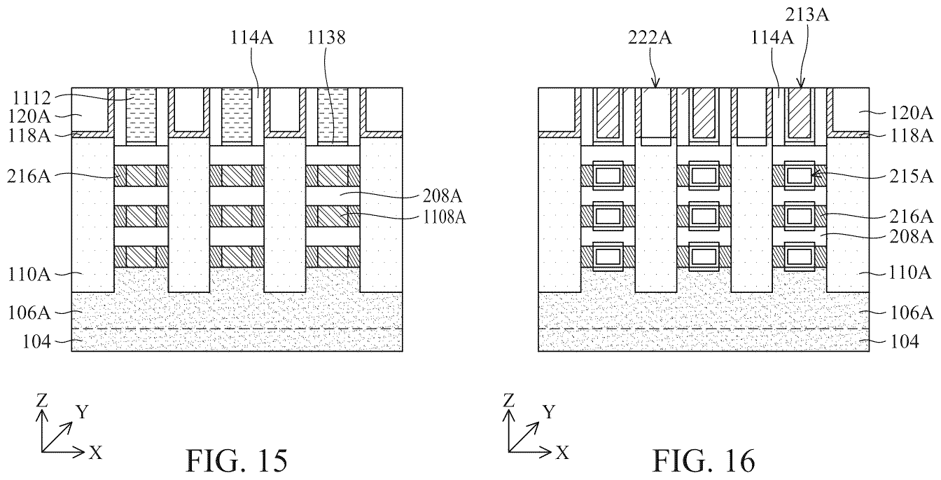

Referring to FIG. 10, in operation 1030, a S/D region is formed in the S/D opening. For example, as shown in FIG. 15, S/D regions 110A are formed in S/D openings 1210. In some embodiments, the formation of S/D regions 110A can include epitaxially growing a semiconductor material (e.g., Si or SiGe) with n-type or p-type dopants in S/D openings 1210, as shown in FIG. 15. The formation of S/D regions 110A can be followed by the formation of ESLs 118A and ILD layers 120A, as shown in FIG. 15.

Referring to FIG. 10, in operation 1035, the polysilicon structure and the nanostructured sacrificial layer are replaced with a gate structure. For example, as shown in FIG. 16, polysilicon structures 1112 and nanostructured sacrificial layers 1108A are replaced with gate structures 112A. The formation of gate structures 112A can include (i) removing polysilicon structures 1112, SiO₂ layers 1138, and nanostructured sacrificial layers 1108A from the structure of FIG. 15 to form gate openings (not shown), and (ii) forming gate structures 112A in the gate openings, as shown in FIG. 16. In some embodiments, the formation of gate structures 112A can be followed by the formation of contact structures 222A on S/D regions 110A, as shown in FIG. 16.

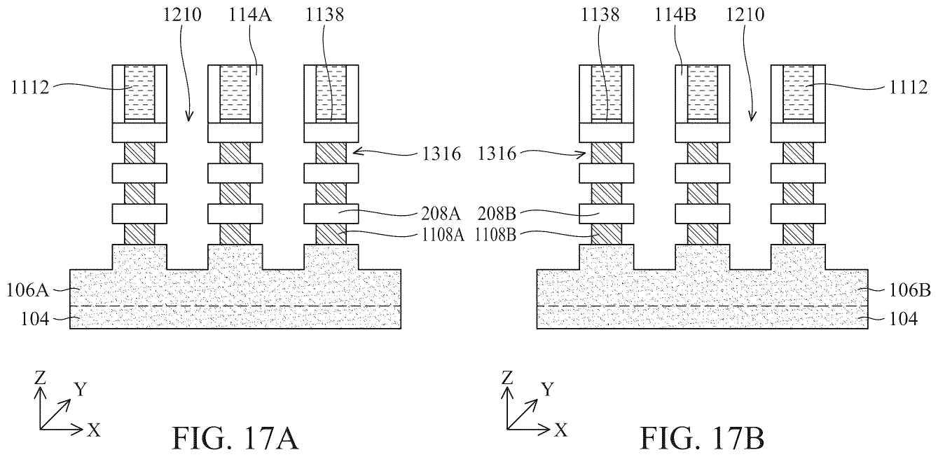

In some embodiments, method 1000 of FIG. 10 can be used to form FETs 102A and 102B substantially parallel to each other on same substrate 104. In some embodiments, the elements of FETs 102A and 102B can be formed at the same time, except for their S/D regions and inner gate spacers, which can be formed sequentially. FIGS. 17A-20A and 17B-20B illustrate the sequential formation of S/D regions 110A and inner gate spacers 216A of FET 102A and S/D regions 110B and inner gate spacers 216B of FET 102B. FIGS. 17A-20A show cross-sectional views of FET 102A along line A-A of FIG. 1 and FIGS. 17B-20B show cross-sectional views of FET 102B along line B-B of FIG. 1 at various stages of their fabrication, according to some embodiments. The discussion of elements in FIGS. 1, 2A, 2B, 11-16, 10A-13A, and 10B-13B with the same annotations applies to each other, unless mentioned otherwise.

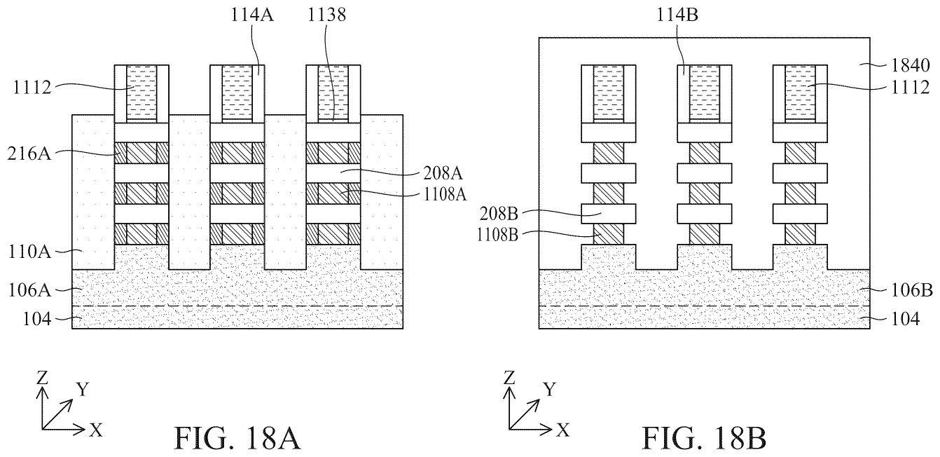

Prior to the formation of S/D regions 110A and 110B, the structures of FIGS. 17A and 17B can be formed by performing operations 1005, 1010, 1015, and 1020 of FIG. 2 on substrate 104. In some embodiments, the formation of S/D regions 109 can be followed by the formation of S/D regions 108. The formation of inner gate spacers 216A and S/D regions 110A can include sequential operations of (i)) depositing a hard mask layer 1840 (e.g., aluminum oxide (AlOₓ) layer) on the structure of FET 102B in FIG. 17B to form the structure of FIG. 18B, (ii) performing operation 1025 of FIG. 10 on the structure of FET 102A in FIG. 10A to form inner gate spacers 216A, as shown in FIG. 18A, (iii) performing operation 1030 of FIG. 10 to form S/D regions 110A, as shown in FIG. 18A, and (iv) removing hard mask layer 1840 from the structure of FIG. 18B. Hard mask layer 1840 can prevent inner gate spacers 216A from being formed in inner gate spacer openings 1316 of FET 102B and S/D regions 110A from being formed in S/D openings 1210 of FET 102B. In some embodiments, inner gate spacers 316A of FIG. 3A can be formed instead of forming inner gate spacers 216A.

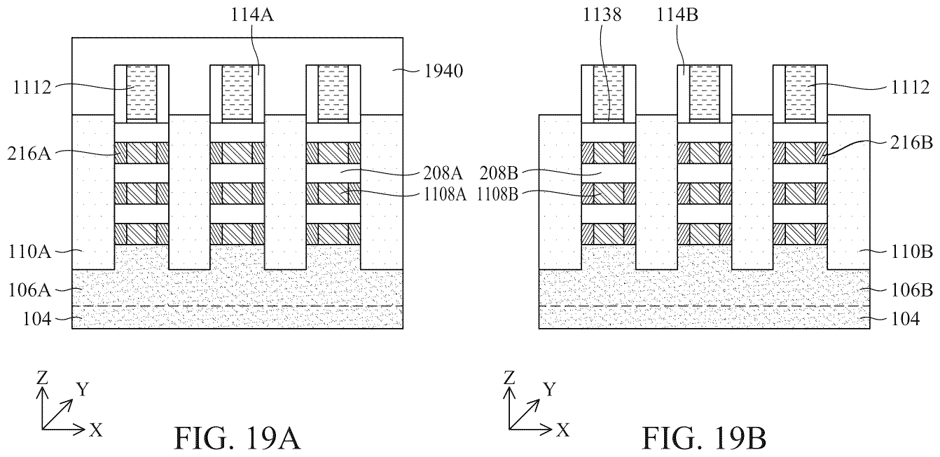

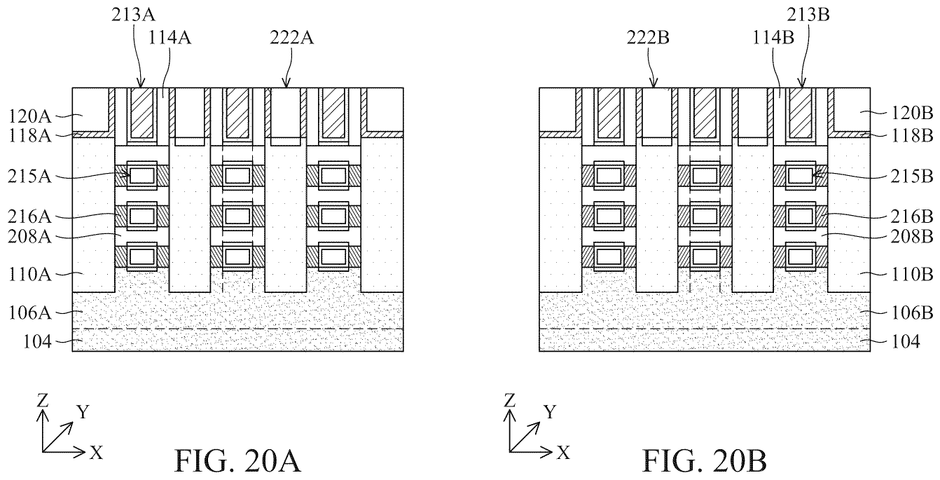

Similar to the formation of inner gate spacers 216A and S/D regions 110A, the formation of inner gate spacers 216B and S/D regions 110B can include sequential operations of (i) depositing a hard mask layer 1940 (e.g., AlOₓ layer) on the structure of FET 102A in FIG. 18A to form the structure of FIG. 19A, (ii) performing operation 1025 of FIG. 10 on the structure of FET 102B after removing hard mask layer 1840 to form inner gate spacers 216B, as shown in FIG. 19B, (iii) performing operation 1030 of FIG. 10 to form S/D regions 110B, as shown in FIG. 19B, and (iv) removing hard mask layer 1940 from the structure of FIG. 19A. Hard mask layer 1940 can prevent inner gate spacers 216B and S/D regions 110B from being formed the structure of FET 102A in FIG. 18A. In some embodiments, inner gate spacers 316B of FIG. 3B can be formed instead of forming inner gate spacers 216B. In some embodiments, the removal of hard mask layer 1940 can be followed by the formation of ESLs 118A and 118B, and ILD layers 120A and 120B, as shown in FIGS. 20A and 20B. The formation of ILD layers 120A and 120B can be followed by operation 1035 of FIG. 10 to form gate structures 112A and 112B in FETs 102A and 102B, as shown in FIGS. 20A and 20B.

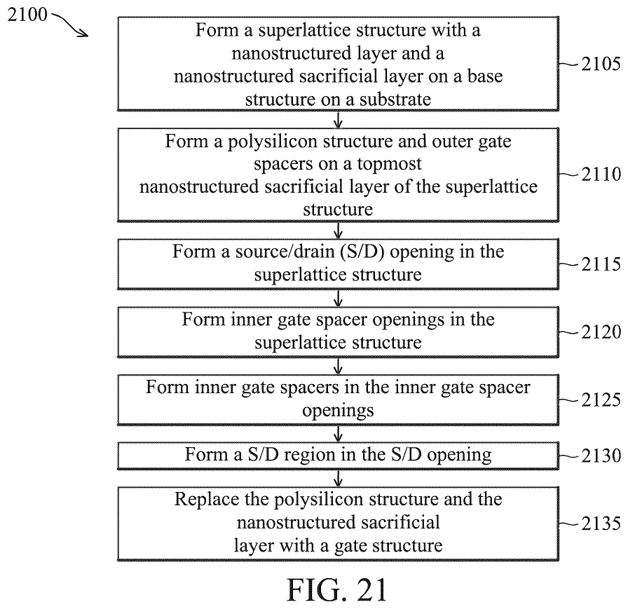

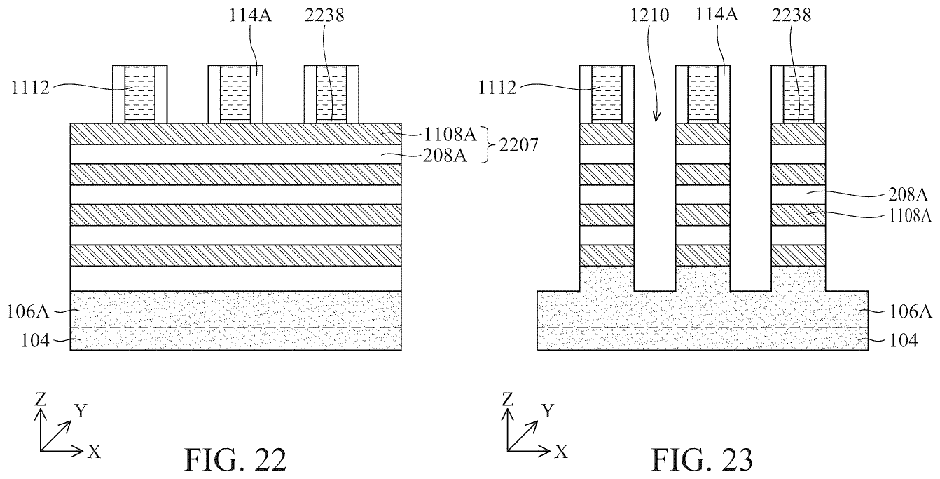

FIG. 21 is a flow diagram of an example method 2100 for fabricating semiconductor device 100 with the cross-sectional view of FIG. 4A, according to some embodiments. For illustrative purposes, the operations illustrated in FIG. 21 will be described with reference to the example fabrication process for fabricating semiconductor device 100 as illustrated in FIGS. 22-27. FIGS. 22-27 are cross-sectional views of semiconductor device 100 at various stages of its fabrication, according to some embodiments. Operations can be performed in a different order or not performed depending on specific applications. It should be noted that method 2100 may not produce a complete semiconductor device 100. Accordingly, it is understood that additional processes can be provided before, during, and after method 2100, and that some other processes may only be briefly described herein. The discussion of elements in FIGS. 1, 2A, 4A, 5A, 11-16, and 22-27 with the same annotations applies to each other, unless mentioned otherwise.

Referring to FIG. 21, in operation 2105, a superlattice structure with a nanostructured layer and a nanostructured sacrificial layer on a base structure on a substrate. For example, as shown in FIG. 22, a superlattice structure 2207 (also referred to as “nanosheet stack 2207”) is formed on base structure 106A, which is formed on substrate 104. Superlattice structure 2207 can include nanostructured layers 208A and nanostructured sacrificial layers 1108A arranged in an alternating configuration. In some embodiments, nanostructured layers 208A can include Si and nanostructured sacrificial layers 1108A can include SiGe.

Referring to FIG. 21, in operation 2110, a polysilicon structure and outer gate spacers are formed on a topmost nanostructured sacrificial layer of the superlattice structure. For example, as shown in FIG. 22, polysilicon structures 1112 and outer gate spacers 114A are formed on topmost nanostructured sacrificial layer 1108A of superlattice structure 2207. In some embodiments, the formation of polysilicon structures 1112 can include sequential operations of (i) depositing a polysilicon layer (not shown) on topmost nanostructured sacrificial layer 1108A of superlattice structure 2207, and (ii) performing a patterning process (e.g., lithography process) on the polysilicon layer to form polysilicon structures 1112, as shown in FIG. 22. In some embodiments, SiGeOₓ layers 2238 can be formed on topmost nanostructured sacrificial layer 1108A prior to the formation of polysilicon structures 1112. During subsequent processing, polysilicon structures 1112, SiGeOₓ layers 2238, and nanostructured sacrificial layers 1108A can be replaced with gate structures 112A in a gate replacement process.

In some embodiments, the formation of outer gate spacers 114A can include sequential operations of (i) depositing a dielectric material layer (not shown) on polysilicon structures 1112 and on exposed regions of topmost nanostructured sacrificial layer 1108A of superlattice structure 2207, (ii) performing an anneal process to densify dielectric material layer, and (iii) etching horizontal portions of the densified dielectric material layer on topmost nanostructured sacrificial layer 1108A to form outer gate spacers 114A, as shown in FIG. 22. In some embodiments, outer gate spacers 614A of FIG. 6A, outer gate spacers 714A of FIG. 7A, or outer gate spacers 814A of FIG. 8A can be formed instead of forming outer gate spacers 114A in the structure of FIG. 22.

Referring to FIG. 21, in operation 2115, a S/D opening is formed in the superlattice structure. For example, as shown in FIG. 23, S/D openings 1210 are formed in superlattice structure 2207. The process of forming S/D openings 1210 in superlattice structure 2207 can be same as the process of forming S/D openings 1210 in superlattice structure 1107 in operation 1015, as described with reference to FIG. 12.

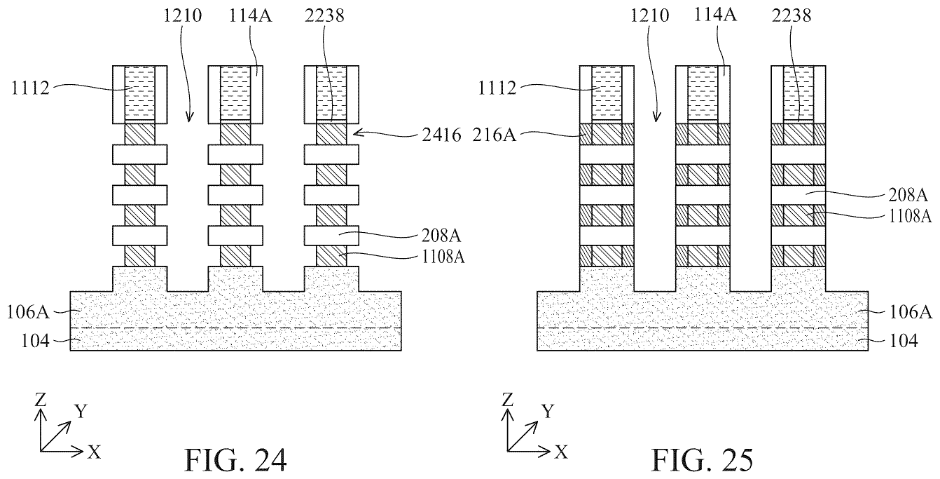

Referring to FIG. 21, in operation 2120, inner gate spacer openings are formed in the superlattice structure. For example, as shown in FIG. 24, inner gate spacer openings 2416 are formed in superlattice structure 2207. The process of forming inner gate spacer openings 2416 in superlattice structure 2207 can be same as the process of forming inner gate spacer openings 1316 in superlattice structure 1107 in operation 1020, as described with reference to FIG. 13. The topmost inner gate spacer openings 2416 can expose the bottom surfaces of outer gate spacers 114A, as shown in FIG. 24, unlike the topmost inner gate spacer openings 1316.

Referring to FIG. 21, in operation 2125, inner gate spacers are formed in the inner gate spacer openings. For example, as shown in FIG. 25, inner gate spacers 216A are formed in inner gate spacer openings 2416. The process of forming inner gate spacers 216A in inner gate spacer openings 2416 can be same as the process of forming inner gate spacers 216A in inner gate spacer openings 1316 in operation 1025, as described with reference to FIG. 14. The topmost inner gate spacers 216A can be formed on the topmost nanostructured layers 208A using method 2100, as shown in FIG. 25, unlike the topmost inner gate spacers 216A of FIG. 14 formed using method 1000. In some embodiments, inner gate spacers 316A of FIG. 3A can be formed in the structure of FIG. 25 instead of forming inner gate spacers 216A in the structure of FIG. 25.

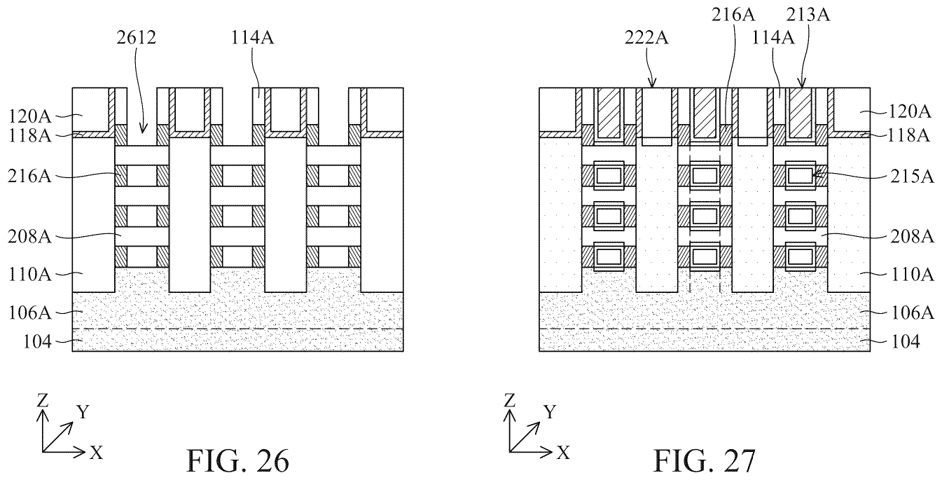

Referring to FIG. 21, in operation 2130, a S/D region is formed in the S/D opening. For example, as shown in FIG. 26, S/D regions 110A are formed in S/D openings 1210. In some embodiments, the formation of S/D regions 110A can include epitaxially growing a semiconductor material (e.g., Si or SiGe) with n-type or p-type dopants in S/D openings 1210, as shown in FIG. 26. The formation of S/D regions 110A can be followed by the formation of ESLs 118A and ILD layers 120A, as shown in FIG. 26.

Referring to FIG. 21, in operation 2135, the polysilicon structure and the nanostructured sacrificial layer are replaced with a gate structure. For example, as described with reference to FIGS. 26 and 27, polysilicon structures 1112 and nanostructured sacrificial layers 1108A are replaced with gate structures 112A. The formation of gate structures 112A can include (i) removing polysilicon structures 1112, SiGeOₓ layers 2238, and nanostructured sacrificial layers 1108A to form gate openings 2612, as shown in FIG. 26, and (ii) forming gate structures 112A in gate openings 2612, as shown in FIG. 27. In some embodiments, the formation of gate structures 112A can be followed by the formation of contact structures 222A on S/D regions 110A, as shown in FIG. 27.

The present disclosure provides example GAA FETs (e.g., FET 102A and 102B) with inner gate spacers (e.g., inner gate spacers 216A, 216B, 316A, 316B, 3016A, and 3016B) that can eliminate the complexities of doping nanostructured channel regions (e.g., nanostructured channel regions 208A and 208B) and minimize variations in the dopant concentrations among the nanostructured channel regions. In some embodiments, each nanostructured channel region can have a core channel region (e.g., core channel regions 208Ac and 208Bc) and extended channel regions (e.g., extended channel regions 208Ae and 208Bc) on either sides of core channel region 208Ac and the nanostructured channel regions can be undoped. The top and bottom surfaces of the extended channel regions can be in contact with the inner gate spacers.

In some embodiments, each of inner gate spacers can include a doped dielectric layer, such as a doped silicon oxide (SiO₂) layer, a doped silicon nitride (SiN) layer, a doped silicon oxynitride (SiON) layer, a doped silicon oxycarbide (SiOC) layer, a doped silicon oxycarbon nitride (SiOCN) layer, and any other suitable doped dielectric layer. In some embodiments, the doped dielectric layer can include dopants, such as aluminum (Al), antimony (Sb), phosphorus (P), chlorine (Cl), fluorine (F), bromine (Br), boron (B), zinc (Zn), magnesium (Mg), germanium (Ge), bismuth (Bi), indium (In), gallium (Ga), and a combination thereof. The dopants in the inner gate spacers can provide a doping effect in the extended channel regions by inducing charge carriers (e.g., electrons or holes) in the extended channel regions. The induced charge carriers can reduce the electrical resistance in the nanostructured channel regions, and improve the drive current through the nanostructured channel regions. Thus, with the presence of dopants in the inner gate spacers, the nanostructured channel regions can have the effect of being doped without the presence of dopants in the nanostructured channel regions. As a result, the need for doping the nanostructured channel regions by ion implantation, by in-situ doped epitaxy, by dopant diffusion, or by any other doping methods can be eliminated and the complexities of manufacturing semiconductor device 100 can be reduced.

In some embodiments, a semiconductor device includes a substrate, first and second nanostructured channel regions disposed on the substrate, first and second source/drain regions disposed adjacent to the first and second nanostructured channel regions, respectively, and first and second gate structures surrounding the first and second nanostructured channel regions, respectively. Each of the first and second nanostructured channel regions includes a core channel region and an extended channel region and each of the first and second gate structures includes an outer gate portion and an inner gate portion. The semiconductor device further includes a first inner gate spacer disposed along a sidewall of the inner gate portion of the first gate structure and a second inner gate spacer disposed along a sidewall of the inner gate portion of the second gate structure. The first inner gate spacer includes a first doped dielectric layer and the second inner gate spacer includes a second doped dielectric layer different from the first doped dielectric layer.

In some embodiments, a semiconductor device includes a substrate, a first nanostructured channel region disposed on a first portion of the substrate, a second nanostructured channel region disposed on the first nanostructured channel region, a first dielectric layer disposed between the first and second nanostructured channel regions, first and second gate structures surrounding the first and second nanostructured channel regions, respectively, a first inner gate spacer disposed along a sidewall of the first gate structure and on a top surface of the first nanostructured channel region, and a second inner gate spacer disposed along a sidewall of the second gate structure and on a bottom surface of the second nanostructured channel region. The first inner gate spacer includes a first doped dielectric layer and the second inner gate spacer includes a second doped dielectric layer different from the first doped dielectric layer.

In some embodiments, a method includes forming a nanostructured layer on a substrate, forming a nanostructured sacrificial layer on the nanostructured layer, forming a polysilicon layer on the nanostructured sacrificial layer, forming an outer gate spacer on the nanostructured sacrificial layer, etching the nanostructured sacrificial layer to form an inner gate spacer opening, depositing a doped liner layer in the inner gate spacer opening, depositing a fill layer on the doped liner layer, forming source/drain region adjacent to the doped layer and the fill layer, and replacing the polysilicon layer and the nanostructured sacrificial layer with a gate structure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
first and second nanostructured channel regions disposed on the substrate, wherein each of the first and second nanostructured channel regions comprises a core channel region and an extended channel region;
first and second source/drain regions disposed adjacent to the first and second nanostructured channel regions, respectively;
first and second gate structures surrounding the first and second nanostructured channel regions, respectively, wherein each of the first and second gate structures comprises an outer gate portion and an inner gate portion;
a first inner gate spacer disposed along a sidewall of the inner gate portion of the first gate structure, wherein the first inner gate spacer comprises a first doped dielectric layer; and
a second inner gate spacer disposed along a sidewall of the inner gate portion of the second gate structure, wherein the second inner gate spacer comprises a second doped dielectric layer different from the first doped dielectric layer.

2. The semiconductor device of claim 1, wherein the first doped dielectric layer comprises n-type dopants, and
wherein the second doped dielectric layer comprises p-type dopants.

3. The semiconductor device of claim 1, wherein the first doped dielectric layer comprises a dopant concentration profile with a decreasing slope.

4. The semiconductor device of claim 1, wherein the first and second doped dielectric layers comprise dopant concentrations different from each other.

5. The semiconductor device of claim 1, wherein the first doped dielectric layer comprises a dopant concentration profile with a decreasing slope from an interface between the first inner gate spacer and the inner gate portion of the first gate structure to an interface between the first inner gate spacer and the first source/drain region.

6. The semiconductor device of claim 1, further comprising a third inner gate spacer disposed along a sidewall of the outer gate portion of the first gate structure, wherein the third inner gate spacer comprises the first doped dielectric layer.

7. The semiconductor device of claim 1, further comprising:
an outer gate spacer disposed along a sidewall of the outer gate portion of the first gate structure; and
a third inner gate spacer disposed between the outer gate spacer and the extended channel region of the first nanostructured channel region.

8. The semiconductor device of claim 1, further comprising:
a first outer gate spacer disposed along a sidewall of the outer gate portion of the first gate structure, wherein the first outer gate spacer comprises the first doped dielectric layer; and
a second outer gate spacer disposed along a sidewall of the outer gate portion of the second gate structure, wherein the second inner gate spacer comprises the second doped dielectric layer.

9. The semiconductor device of claim 1, wherein the first doped dielectric layer comprises:
a fill layer; and
a liner layer with a C-shaped cross-sectional profile surrounding the fill layer.

10. The semiconductor device of claim 1, further comprising an outer gate spacer disposed along a sidewall of the outer gate portion of the first gate structure, wherein the outer gate spacer comprises:
a fill layer comprising a first dopant concentration; and
a liner layer comprising a second dopant concentration greater than the first dopant concentration.

11. A semiconductor device, comprising:
a substrate;
a first nanostructured channel region disposed on a first portion of the substrate;
a second nanostructured channel region disposed on the first nanostructured channel region;
a first dielectric layer disposed between the first and second nanostructured channel regions;
first and second gate structures surrounding the first and second nanostructured channel regions, respectively;
a first inner gate spacer disposed along a sidewall of the first gate structure and on a top surface of the first nanostructured channel region, wherein the first inner gate spacer comprises a first doped dielectric layer; and
a second inner gate spacer disposed along a sidewall of the second gate structure and on a bottom surface of the second nanostructured channel region, wherein the second inner gate spacer comprises a second doped dielectric layer different from the first doped dielectric layer.

12. The semiconductor device of claim 11, wherein the first and second doped dielectric layers comprise dopant concentrations different from each other.

13. The semiconductor device of claim 11, wherein the first doped dielectric layer comprises p-type dopants, and
wherein the second doped dielectric layer comprises n-type dopants.

14. The semiconductor device of claim 11, wherein the first doped dielectric layer comprises:
a fill layer comprising a first dopant concentration; and
a liner layer comprising a second dopant concentration greater than the first dopant concentration.

15. The semiconductor device of claim 11, further comprising a third inner gate spacer disposed on a top surface of the second nanostructured channel region, wherein the third inner gate spacer comprises the second doped dielectric layer.

16. The semiconductor device of claim 11, further comprising a source/drain regions adjacent to the first nanostructured channel region, wherein the first doped dielectric layer comprises a dopant concentration profile with a decreasing slope from an interface between the first inner gate spacer and the first gate structure to an interface between the first inner gate spacer and the source/drain region.

17. A method, comprising:
forming a nanostructured layer on a substrate;
forming a nanostructured sacrificial layer on the nanostructured layer;
forming a polysilicon layer on the nanostructured sacrificial layer;
forming an outer gate spacer on the nanostructured sacrificial layer;
etching the nanostructured sacrificial layer to form an inner gate spacer opening;
depositing a doped liner layer in the inner gate spacer opening;
depositing a fill layer on the doped liner layer;
forming source/drain region adjacent to the doped layer and the fill layer; and
replacing the polysilicon layer and the nanostructured sacrificial layer with a gate structure.

18. The method of claim 17, further comprising performing an annealing process on the fill layer.

19. The method of claim 17, wherein depositing the fill layer comprises depositing a doped fill layer with a dopant concentration lower than a dopant concentration of the liner layer.

20. The method of claim 17, wherein forming the outer gate spacer comprises:
depositing an other doped liner layer on the polysilicon layer; and
depositing an other fill layer on the doped liner layer.
